(19) United States
(12) Patent Application Publication
(10) Pub. No.: US 2025/0331302 A1
(43) Pub. Date: Oct. 23, 2025

(54) COMPLEMENTARY FET STRUCTURES WITH REDUCED AREA

(71) Applicant: Taiwan Semiconductor Manufacturing Company Ltd., Hsinchu (TW)

(72) Inventors: Yang-Hsin Shih, Hsinchu (TW); Yi Wei Pan, Hsinchu (TW); Ying Chih Chen, Hsinchu (TW); Pin-Dai Sue, Hsinchu (TW); Kao-Cheng Lin, Hsinchu (TW)

(73) Assignee: Taiwan Semiconductor Manufacturing Company Ltd., Hsinchu (TW)

(21) Appl. No.: 18/642,273

(22) Filed: Apr. 22, 2024

(51) Int. Cl. H01L 27/092; H01L 21/822; H01L 21/8238; H01L 23/528; H01L 29/06; H01L 29/417; H01L 29/423; H01L 29/66; H01L 29/775

(52) U.S. Cl. CPC H10D 84/856; H01L 23/5286; H10D 30/014; H10D 30/43; H10D 30/6729; H10D 30/6735; H10D 62/121; H10D 64/017; H10D 64/018; H10D 84/0186; H10D 84/038; H10D 88/01

(57) ABSTRACT

A semiconductor device includes a first semiconductor layer and a second semiconductor layer stacked vertically over a substrate. The first semiconductor layer and the second semiconductor layer extend laterally across the substrate. The semiconductor device includes a first gate structure and a second gate structure extending vertically from the substrate and perpendicular to the first semiconductor layer and the second semiconductor layer. The first gate structure engages the first semiconductor layer and the second semiconductor layer to form a first transistor and a second transistor, respectively. The second gate structure engages the first semiconductor layer and the second semiconductor layer to form a third transistor and a fourth transistor, respectively. The first gate structure is laterally adjacent to the second gate structure. The third transistor is an inactive transistor. The second transistor and the fourth transistor are active transistors.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of advanced IC structures, such as vertically stacked complementary field-effect transistors, or CFETs. While current designs of CFETs are generally adequate, they are not entirely satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows a schematic perspective view of an example vertically arranged complementary FET (CFET), according to some embodiments of the present disclosure.

FIG. 2A shows a schematic perspective view of an example CFET, according to some embodiments of the present disclosure.

FIG. 2B shows a circuit diagram corresponding to the example CFET of FIG. 2A, according to some embodiments of the present disclosure.

FIGS. 3 and 6 each show a schematic cross-sectional view of an example CFET along a direction corresponding to line LL′ depicted in FIG. 2A, according to some embodiments of the present disclosure.

FIGS. 4 and 5 each show a schematic perspective view of a portion of the example CFET of FIG. 3, according to some embodiments of the present disclosure.

FIG. 7 shows a schematic perspective view of a portion of the example CFET of FIG. 6, according to some embodiments of the present disclosure.

FIGS. 8, 10, and 12 each show a schematic cross-sectional view of an example CFET along a direction corresponding to line LL′ depicted in FIG. 2A, according to some embodiments of the present disclosure.

FIGS. 9, 11, and 13 each show a schematic perspective view of a portion of the example CFET of FIGS. 8, 10, and 12, respectively, according to some embodiments of the present disclosure.

FIGS. 14 and 15 each show a schematic cross-sectional view of an example CFET along a direction corresponding to line LL′ depicted in FIG. 2A, according to some embodiments of the present disclosure.

FIGS. 16, 17, 18, and 19 each show a schematic cross-sectional view of an example CFET along a direction corresponding to line LL′ depicted in FIG. 2A, according to some embodiments of the present disclosure.

FIG. 20 shows a schematic perspective view of an example CFET, in accordance with some embodiments.

FIG. 21 shows a schematic perspective view of a portion of the example CFET of FIG. 20 during an intermediate step of a fabrication process, in accordance with some embodiments of the present disclosure.

FIGS. 22, 23, 24, and 25 each show a schematic cross-sectional view of the example CFET of FIG. 20 along a direction corresponding to line AA′ of FIG. 21 during an intermediate step of a fabrication process, according to some embodiments of the present disclosure.

FIGS. 26A and 26B show a flowchart of an example fabrication process of forming the example CFET of FIG. 20, according to some embodiments of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.”

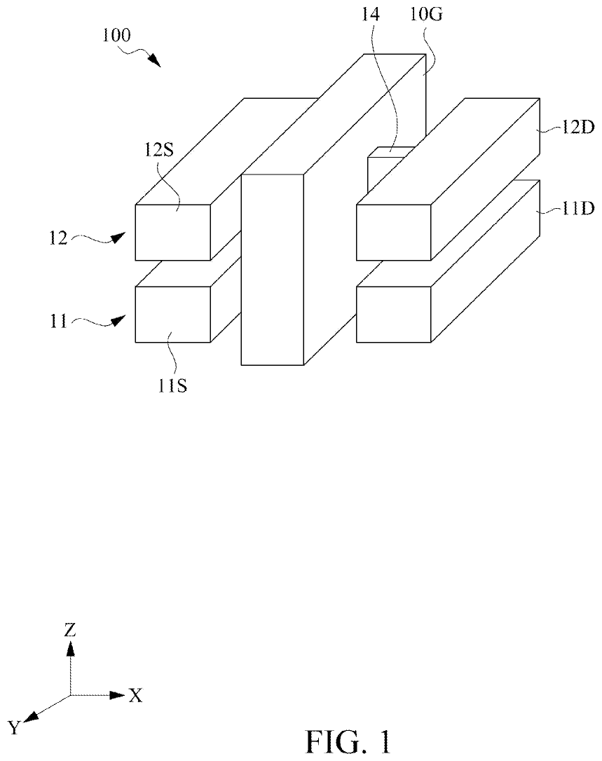

FIG. 1 illustrates a device 100 that includes a first (e.g., bottom or lower) field-effect transistor (FET) 11 disposed over a substrate (not depicted) and a second (e.g., top or upper) FET 12 is disposed above the first FET 11, such that the first FET 11 and the second FET 12 are stacked vertically over the substrate in a thickness direction of the substrate. The thickness direction of the substrate is designated as the Z axis in FIG. 1 and all subsequent figures. In the depicted embodiment, the first FET 11 is disposed vertically between the substrate and the second FET 12. Though not depicted in detail in FIG. 1, the first FET 11 and the second FET 12 may each be configured as a multi-channel device, such as a nanosheet FET, nanowire FET, or the like. Other device configurations may also be applicable to embodiments of the present disclosure. In some embodiments, the first FET 11 and the second FET 12 have different device configurations. For example, the first FET 11 is a planar FET, while the second FET 12 is a nanosheet FET.

The device 100 includes a first source contact 11S and a first drain contact 11D respectively coupled to a source region (not depicted) and a drain region 14 of the first FET 11. Source/drain (S/D) region(s) may refer to a source or a drain, individually or collectively dependent upon the context and are configured to provide S/D features discussed in detail below. The first source contact 11S and the first drain contact 11D are collectively referred to as S/D contacts of the first FET 11. The device 100 also includes a second source contact 12S and a second drain contact 12D respectively coupled to a source region (not depicted) and a drain region (not depicted) of the second FET 12. The second source contact 12S and the second drain contact 12D are collectively referred to as S/D contacts of the second FET 12. The S/D regions of the first FET 11 are electrically separated from the S/D regions of the second FET 12 in some embodiments.

A gate structure 10G, including a gate dielectric layer (not depicted) and a gate electrode layer (not depicted), traverses, engages, or wraps around a channel region of each of the first and second FETs. In some embodiments, the first FET 11 is of a first conductivity type, such as n-type, where the first FET 11 is alternatively referred to as an n-type metal-oxide-semiconductor, or NMOS, device, and the second FET 12 is a of a second conductivity type different from the first conductivity type, such as p-type, where the second FET 12 is alternatively referred to as a PMOS device. In this regard, the device 100 is configured as a P-on-N structure (e.g., a P-on-N CFET). In some embodiments, the first FET 11 is a PMOS device, the second FET 12 is an NMOS device, and the device 100 is configured as an N-on-P structure (e.g., an N-on-P CFET). In some embodiments, the first and second FETs have the same conductivity type, such as both are of n-type (forming an N-on-N structure) or both are of p-type (forming a P-on-P structure).

In some embodiments, though not depicted, one of the S/D contacts (e.g., the second drain contact 12D) of the second FET 12 is coupled to a first power supply line (or power), e.g., Vdd, and one of the S/D contacts (e.g., 11S) of the first FET 11 is coupled to a second power supply line (or ground), e.g., Vss.

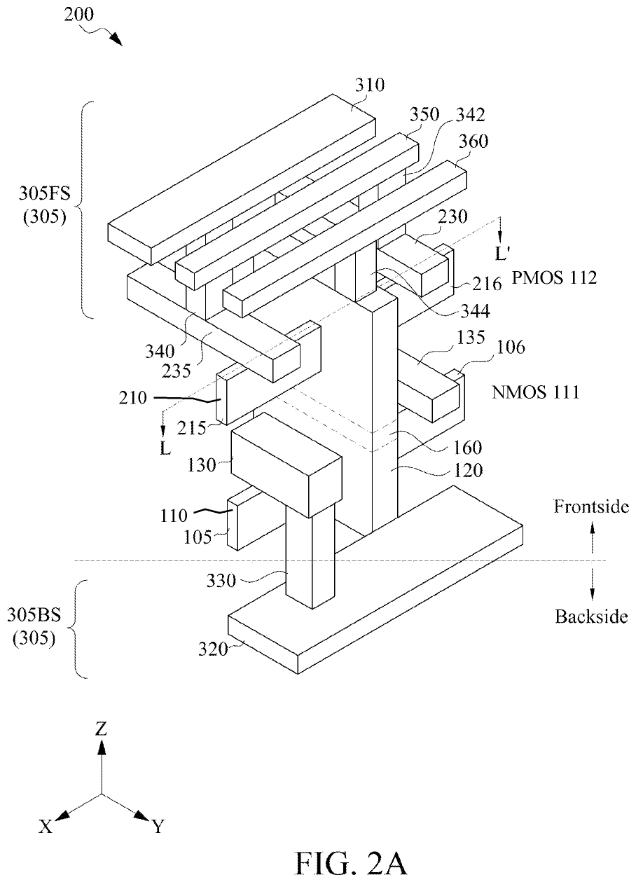

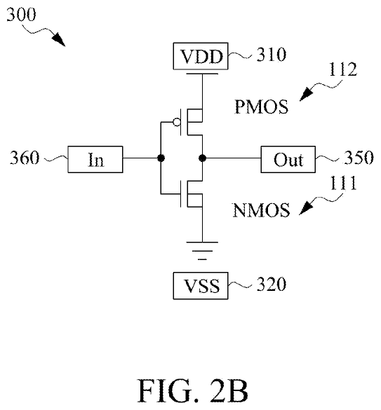

FIG. 2A depicts a schematic perspective view of a vertically arranged CFET device 200 (hereafter referred to as the device 200) according to some embodiments of the present disclosure. FIG. 2B depicts a circuit diagram 300 corresponding to an embodiment of the device 200. In some embodiments, the device 200 is similar to the device 100 in that the device 200 includes a first FET 111 and a second FET 112 stacked vertically over a substrate (not depicted), where the first FET 111 is disposed between the substrate and the second FET 12 along the Z axis as depicted. Though not depicted in detail in FIG. 2A, the first FET 111 and the second FET 112 may each be configured as a multi-channel device, such as a nanosheet FET, nanowire FET, or the like. Other device configurations may also be applicable to embodiments of the present disclosure. In some embodiments, the first FET 111 and the second FET 112 have different device configurations. For example, the first FET 111 is a FET device, while the second FET 112 is a nanosheet FET.

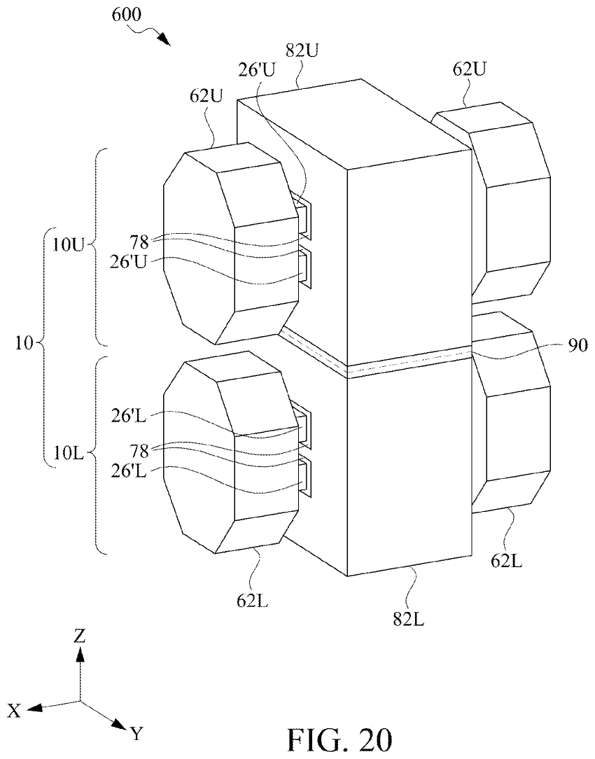

The first FET 111 includes a first semiconductor layer (or first active region) 110 extending lengthwise along a first lateral direction (e.g., the X-axis) over the substrate, and the second FET 112 includes a second semiconductor layer (or second active region) 210 extending above and parallel to the first semiconductor layer 110. Each of the first semiconductor layer 110 and the second semiconductor layer 210 may alternatively be referred to as a fin, a nanosheet, a nanowire, for example. The first semiconductor layer 110 includes a pair of S/D regions 105 and 106 and a channel region (not depicted) interposed between the S/D regions 105 and 106 along the first lateral direction. Similarly, the second semiconductor layer 210 includes a pair of S/D regions 215 and 216 and a channel region (not depicted) interposed between the S/D regions 215 and 216. Although only one first semiconductor layer 110 and one second semiconductor layer 210 are depicted herein, it is understood that the device 200 may include any suitable number of each of the semiconductor layers 110 and 210 stacked vertically over the substrate. For example, the first semiconductor layer 110 may be a lower portion of a multilayer structure (e.g., one of the second semiconductor layers 26′L of the multilayer structure 22′ as depicted in FIGS. 20-25) and the second semiconductor layer 210 may be an upper portion of the multilayer structure (e.g., one of the second semiconductor layers 26′U of the multilayer structure 22′ as depicted in FIGS. 20-25) above the lower portion.

The substrate includes a semiconductor substrate (or semiconductor layer), such as a bulk semiconductor, a semiconductor-on-insulator (SOI) substrate, or the like, which may be doped (e.g., with a p-type or an n-type dopant) or undoped. The substrate may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multilayered or gradient substrate may also be used. In some embodiments, the semiconductor material of the substrate may include silicon (Si); germanium (Ge); a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GalnP, and/or GaInAsP; or combinations thereof. In some embodiments, the substrate includes a p-type silicon substrate (p-substrate). For example, p-type dopants are introduced into the substrate to form the p-substrate.

In some embodiments, the semiconductor layers 110 and 210 each include a crystalline semiconductor material similar to the composition of the substrate described above. For example, the semiconductor layers 110 and 210 may each include Si, SiGe, Ge, SiGeSn, GaAs, InSb, GaP, GaSb, AlInAs, AlGaAs, GalnAs, GaSbP, GaAsP, GaAsSb InP, GalnP, GalnAsP, the like, or combinations thereof. In some embodiments, the semiconductor layers 110 and 210 both include Si.

In some embodiments, the channel region (e.g., the semiconductor layer 110) of the first FET 111 and the channel region (e.g., the semiconductor layer 210) of the second FET 112 include the same material, such as Si. In some embodiments, the channel region of the first FET 111 and the channel region of the second FET 112 include different materials. For example, the channel region of the first FET 111 includes Si and the channel region of the second FET 112 includes SiGe.

The S/D regions of each of the semiconductor layers 110 and 210 are doped with a suitable dopant for providing the first FET 111 and the second FET 112, respectively. For example, the S/D regions 105 and 106 may be doped with an n-type dopant, such as phosphorous (P), arsenic (As), the like, or combinations thereof, such that the first FET 111 is formed as an n-type FET (NMOS), and the S/D regions 215 and 216 may be doped with a p-type dopant, such as boron (B), gallium (Ga), indium (In), the like, or combinations thereof, such that the second FET 112 is formed as a p-type FET (PMOS).

In some embodiments, the S/D regions 105 and 106 may each include an epitaxially grown semiconductor structure (e.g., an n-type doped epitaxially grown semiconductor structure) from the corresponding regions of the first semiconductor layer 110, and the S/D regions 215 and 216 may each include an epitaxially grown semiconductor structure (e.g., a p-type doped epitaxially grown semiconductor structure) from the corresponding regions of the second semiconductor layer 210. In some embodiments, the S/D regions 105, 106 and the S/D regions 215, 216 are each epitaxially grown as a raised semiconductor structure.

Though not depicted, the device 200 further includes a plurality of isolation structures configured to isolate various conductive features of the device 200. The isolation structures may include isolation structures (e.g., shallow-trench isolation, or STI) formed on the substrate, an interlayer dielectric (ILD) layer surrounding the S/D regions of the semiconductor layers 110 and 210, and intermetal dielectric (IMD) layers each surrounding various contacts, interconnect structures, signal lines, and power rails. The various isolation structures may each include an oxide (e.g., silicon oxide), a nitride (e.g., silicon nitride), a low-k (e.g., having a dielectric constant less than that of silicon oxide, which is about 3.9) dielectric material (e.g., phosphosilicate glass (PSG), borosilicate glass (BSG), boron-doped phosphosilicate glass (BPSG), undoped silicate glass (USG), etc.), the like, or combinations thereof.

The device 200 includes a gate structure 120 that extends vertically (e.g., along the Z axis) from the substrate and lengthwise along a second lateral direction (e.g., along the Y axis) perpendicular to the first lateral direction. The gate structure 120 wraps around or engage the channel region of each of the semiconductor layers 110 and 210. As such, the gate structure 120 forms the first FET 111 with the S/D regions 105 and 106 and the second FET 112 with the S/D regions 215 and 216. Although only one gate structure 120 is depicted herein, it is understood that the device 200 may include any suitable number of the gate structures 120 extending from the substrate and spaced apart along the first lateral direction (e.g., along the X-axis), each gate structure 120 engaging with a channel region of the semiconductor layers 110 and 210 to form additional FETs.

In some embodiments, the gate structure 120 extends continuously between the first semiconductor layer 110 and the second semiconductor layer 210. In some embodiments, the device 200 includes a gate isolation structure 160 separating the gate structure 120 into a first (bottom or lower) portion that wraps around the first semiconductor layer 110 and a second (top or upper) portion that wraps around the second semiconductor layer 210. The gate isolation structure 160 may include any suitable dielectric material, such as an oxide (e.g., silicon oxide), a nitride (e.g., silicon nitride), the like, or combinations thereof.

The gate structure 120 incudes at least a gate dielectric layer (not depicted) and a gate electrode layer (not depicted) over the gate dielectric layer. in some embodiments. The gate dielectric layer may include any suitable dielectric material, such as silicon oxide, silicon nitride, a high-k dielectric material (i.e., having a dielectric constant greater than that of silicon oxide, which is about 3.9), the like, or combinations thereof. The high-k dielectric material may include an oxide or a silicate of Hf, Al, Zr, La, Mg, Ba, Ti, Pb, the like, or combinations thereof. In some embodiments, the gate dielectric layer includes an interfacial layer formed between the channel region of each of the semiconductor layers 110 and 210 and the gate dielectric layer.

The gate electrode layer is formed on the gate dielectric layer to surround each channel region of the semiconductor layers 110 and 210. The gate electrode layer may include any suitable metal, such as tungsten (W), copper (Cu), ruthenium (Ru), aluminum (Al), gold (Au), cobalt (Co), titanium (Ti), tantalum (Ta), molybdenum (Mo), TiN, TaN, WN, TiAl, TiAlN, TaCN, TaC, TaSiN, metal alloys, the like, or combinations thereof.

In some embodiments, the gate structure 120 includes one or more work function layers disposed between the gate dielectric layer and the gate electrode layer. The work function layers may include a p-type work function layer, an n-type work function layer, multilayers thereof, or combinations thereof. Examples of the work function layers may include TiN, TaN, Ru, Mo, Al, ZrSi₂, MoSi₂, TaSi₂, NiSi₂, WN, Ti, Ag, TaAl, TaAlC, TiAlN, TaC, TaCN, TaSiN, Mn, Zr, the like, or combinations thereof.

Though not depicted, the device 200 may include gate spacers disposed along sidewalls of the gate structure 120. The gate spacers are configured to electrically isolate the gate structure 120 from adjacent conductive features, such as a source contact 130 and a drain contact 135 coupled to the S/D regions 105 and 106, respectively, and a source contact 230 and a drain contact 235 coupled to the S/D regions 215 and 216, respectively. The gate spacers may include one or more layers of a suitable dielectric material, such as silicon nitride, silicon oxynitride, silicon carbonitride, a low-k material described above, the like, or combinations thereof.

In the depicted embodiments, the source contact 130 is coupled to the source region 105, the drain contact 135 is coupled to the drain region 106, the source contact 230 is coupled to the source region 216, and the drain contact 235 is coupled to the drain region 215. Each of the S/D contacts, collectively referring to the source contact 130, the drain contact 135, the source contact 230, and the drain contact 235, may include a metal fill layer containing any suitable metal, such as tungsten (W), copper (Cu), ruthenium (Ru), aluminum (Al), gold (Au), cobalt (Co), the like, or combinations thereof. In some embodiments, each S/D contact further includes a barrier layer (not depicted) disposed between each corresponding S/D region and the metal fill layer. The barrier layer may include any suitable material, such as titanium (Ti), tantalum (Ta), titanium nitride (TiN), tantalum nitride (TaN), the like, or combinations thereof. In some embodiments, the device 200 includes a silicide layer (not depicted) including a metal silicide, for example, between each S/D contact and the corresponding S/D region.

In some embodiments, still referring to FIG. 2A, one of the power supply lines (power rails) Vdd 310 (e.g., positive potential) and Vss 320 (e.g., negative or ground potential) for supplying power to the FETs 111 and 112, which are configured to form a CFET in some embodiments, is located below the CFET and the other of the power supply lines is located above the CFET. For example, the source contact 130 of the first FET 111 is coupled to a first power supply line Vss 320 through a bottom via contact 330, while the drain contact 235 of the second FET 112 is coupled to a second power supply line Vdd 310 through a top via contact 340. The first power supply line Vss 320 is located below the first FET 111 (and above the substrate) and the second power supply line Vdd 310 is located above the second FET 112 in some embodiments. In some embodiments, the first power supply line Vss 320 and the second power supply line Vdd 310 are both located above the second FET 112 or both below the first FET 111 (and above the substrate).

In some embodiments, signal lines 350 and 360 are disposed above or over the second FET 112 as shown in FIG. 2A. In some embodiments, the signal line 350 is coupled to the source contact 230 of the second FET 112 through a via contact 342, and the signal line 360 is coupled to the gate structure 120 of the CFET through a via contact 344. In some embodiments, the signal line 360 is an input of the inverter and the signal line 350 is an output of the inverter.

In some embodiments, the second power supply line Vdd 310 and the signal lines 350 and 360 are formed in the same metallization layer (e.g., M0), and the top via contact 340 and the via contacts 342 and 344 are formed in the same via level (e.g., V0). In some embodiments, the various interconnect structures (e.g., via contacts), signal lines (the signal lines 350 and 360), and power rails (the power supply lines Vdd 310 and Vss 320) are configured as components of a multilayer interconnect (MLI) structure 305, which may include a frontside portion 305FS and a backside portion 305BS opposite the frontside portion 305FS. The frontside portion 305FS includes those components (e.g., the second power supply line Vdd 310, the signal lines 350 and 360, etc.) formed over a frontside of the substrate, and the backside portion 305BS includes those components (e.g., the first power supply line Vss 320) formed over a backside of the substrate opposite the frontside. In some embodiments, the various interconnect structures (e.g., via contacts), signal lines (the signal lines 350 and 360), and power rails (the power supply lines Vdd 310 and Vss 320) are all configured as components of the frontside portion 305FS.

Referring to FIGS. 2A and 2B, the first FET 111 (e.g., an NMOS) and the second FET 112 (e.g., a PMOS) may be configured to form a cross-coupled inverter (e.g., a CFET). In this regard, as depicted in the circuit diagram 300, the common gate structure 120 is coupled to the signal line (input) 360, the drain contact 135 and the source contact 230 are coupled to the signal line (output) 350, the source contact 130 is coupled to the first power supply line Vss 320, and the drain contact 235 is coupled to the second power supply line Vdd 310.

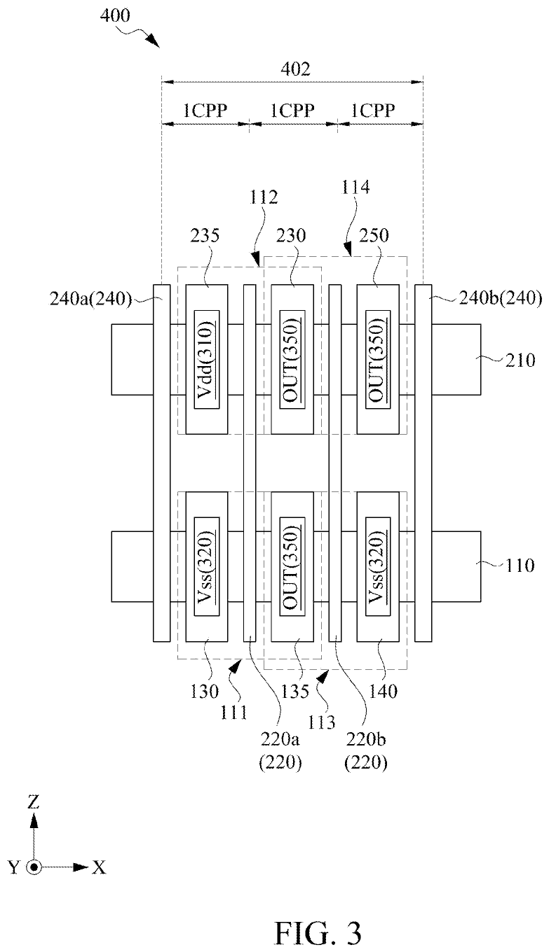

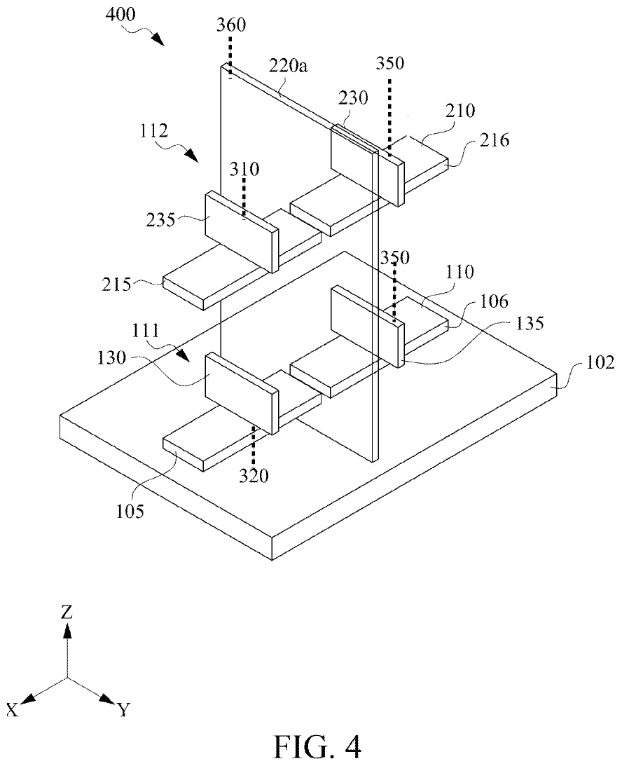

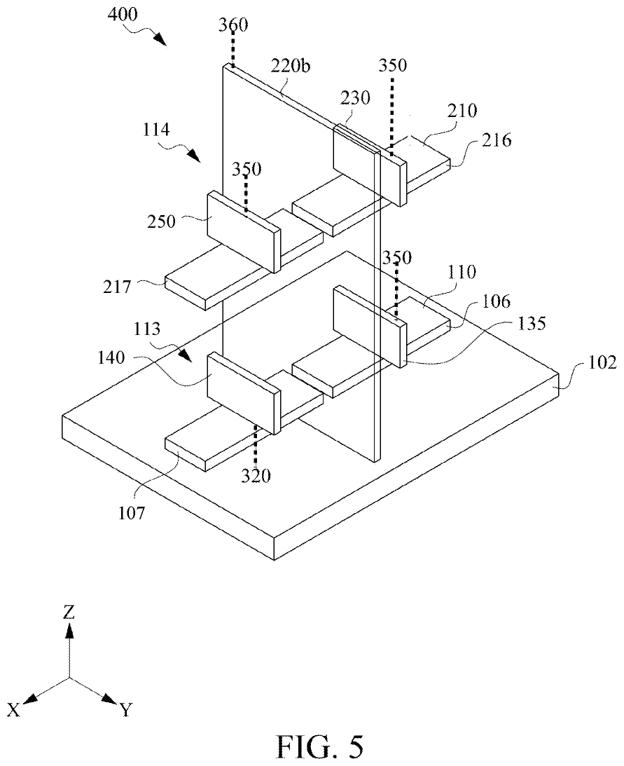

FIGS. 3-7 illustrate various embodiments of a vertically stacked device (or device) 400, or portions thereof. The device 400 is similar to the device 200 in that the device 400 also includes two transistors, the first FET 111 and the second FET 112, vertically stacked over a substrate 102 (depicted in FIGS. 4 and 5, for example), where the first FET 111 and the second FET 112 each include components coupled to various signal lines, such as the signal lines 350 and 360, and to various power supply lines, such as the power supply lines Vss 320 and Vdd 310, similar to the corresponding components of the device 200. As such, the components common between the devices 200 and 400 are labeled using the same reference numerals and their descriptions are not repeated for purposes of brevity.

Different from the device 200, referring to FIG. 3, the device 400 includes two parallel gate structures 220a and 220b (collectively referred to as the gate structures 220) each wrapping around channel regions of the semiconductor layers 110 and 210. In this regard, the device 400 includes two additional FETs, a third FET 113 laterally adjacent the first FET 111 along the X-axis, and a fourth FET 114 laterally adjacent the second FET 112 along the X-axis and vertically above and aligned with the third FET 113 along the Z axis. In some embodiments, the first FET 111 and the third FET 113 are configured as NMOS devices, and the second FET 112 and the fourth FET 114 are configured as PMOS devices. As such, at least a portion of the device 400 is configured as a CFET in a manner similar to the device 200 described above. In some embodiments, the FETs formed in the first semiconductor layer 110 have the same conductivity type as those formed in the second semiconductor layer 210.

FIG. 3 illustrates a cross-sectional view of the device 400 along a direction corresponding to line LL′ depicted in FIG. 2A, i.e., along the first lateral direction through the semiconductor layers 110 and 210. FIG. 4 illustrates a perspective view of the device 400 depicting a first gate structure 220a, i.e., the first FET 111 and the second FET 112. FIG. 5 illustrates a perspective view of the device 400 depicting a second gate structure 220b, i.e., the third FET 113 and the fourth FET 114. In the present embodiments, the first FET 111, the second FET 112, and the third FET 113 are active (or functional) FETs, while the fourth FET 114 is an inactive or dummy FET described in greater detail below.

The third FET 113 is formed in the first semiconductor layer 110, which includes the drain region 106, a common drain region (or terminal) shared with the first FET 111, and a source region 107, as depicted in FIG. 5. In this regard, the drain region 106 is coupled to the drain contact 135 as described above and the source region 107 is coupled to a source contact 140, as depicted in FIGS. 3 and 5. The fourth FET 114 is formed in the second semiconductor layer 210, which includes the source region 216, a common source region shared with the second FET 112, and a drain region 217, as depicted in FIG. 5. In this regard, the source region 216 is coupled to the source contact 230 as described above and the drain region 107 is coupled to a drain contact 250, as depicted in FIGS. 3 and 5.

As described above, terminals, i.e., the source, the drain, and the gate, of the FETs 111 and 112 are coupled to different signal lines and/or power supply line, rendering the FETs 111 and 112 functional (hereafter used interchangeably with “active”). For example, the source contact 130 of the FET 111 is coupled to the first power supply line Vss 320, and the drain contact 135 of the FET 111 is coupled to the signal line 350. Similarly, the source contact 230 of the FET 112 is coupled to the signal line 350, and the drain contact 235 of the FET 112 is coupled to the second power supply line Vdd 310. The first gate structure 220a, which commonly engage channel regions of both semiconductor layers 110 and 210, is coupled to the signal line 360.

Still referring to FIG. 3, the third FET 113, whose structure may be a mirror image of that of the first FET 111 about the Z axis, also includes terminals coupled to different signal lines and power supply line. For example, the drain contact 135, which is shared with the first FET 111, is coupled to the signal line 350, the source contact 140 is coupled to the first power supply line Vss 320, and the second gate structure 220b, which is shared with the fourth FET 114, is coupled to the signal line 360. In contrast, as depicted in FIGS. 3 and 5, the source contact 230, which is shared with the second FET 112, and the drain contact 250 of the fourth FET 114 are both coupled to the signal line 350, rendering the fourth FET 114 a dummy (hereafter used interchangeably with “inactive”) FET.

In the present embodiments, referring to FIG. 3, the device 400 further includes dielectric structures 240a and 240b (collectively referred to as dielectric structures 240) each extending from the substrate 102 and parallel to the gate structures 220. In some embodiments, each dielectric structure 240 is disposed laterally between S/D regions of two adjacent FETs to truncate or separate each active region (e.g., the semiconductor layers 110 and 210). In this regard, the dielectric structures 240 define “edges” of adjacent FETs and may therefore be referred to as cut polysilicon on diffusion edge (CPODE) structures. In the present embodiments, the dielectric structure 240a extends continuously alongside the S/D contacts 130 and 235, while the dielectric structure 240b extends continuously alongside the S/D contacts 140 and 250. Each dielectric structure 240 is separated from a closest gate structure 220 by the same gate pitch as that between two adjacent gate structures 220. In this regard, a portion of the device 400 between two adjacent dielectric structures 240 has an area that varies with a separation distance (e.g., a length) 402, which is equivalent to three (3) center polysilicon pitch, or CPP, in the depicted embodiment. A CPP is defined as a pitch measured between centerlines of two adjacent gate structures 220 and/or dielectric structures 240.

During or after fabrication of various transistors in a device (e.g., the device 400), certain transistors (e.g., the FETs 111, 112, 113, and 114) may be isolated from one another by forming “cuts” through the active regions in which the transistors are formed. For instance, an etching process or technique, such as a CPODE technique, can be used to pattern the transistors by truncating or separating adjacent transistors from one another along a lengthwise direction of the active region (e.g., the X-axis as depicted). The cuts can then be filled with a dielectric material, such as an oxide or a nitride, to electrically isolate the adjacent transistors from one another. In this regard, the number of the CPODE structures (i.e., the dielectric structures 240) formed in a device is generally equal to a number of transistors needing isolation plus one.

For a vertically arranged CFET, as depicted herein, such cuts vertically extend through both the top (i.e., the second semiconductor layer 210) and the bottom (i.e., the first semiconductor layer 110) levels of the device, which may include different numbers of transistors. For example, the bottom level may include at least one more transistor than the top level, or vice versa. In existing technologies, the number of the CPODE structures formed in the device, and thus an area of the device (in terms of CPP, for example), is determined by the level (top or bottom) of the device that includes a greater number of transistors. While this approach is generally adequate, it results in unused area in the level of the device having a fewer number of transistors. For example, in a CFET having two functional NMOS devices on a bottom level and one functional PMOS device on a top level, a total of three (3) dielectric structures are generally formed parallel to gate structures, where one of the dielectric structures vertically extends adjacent to the PMOS device in the top level and between the two NMOS devices in the bottom level. Such an arrangement results in an area (e.g., a cell) of the device having a length of four (4) CPP (three transistors plus one) in the X-axis as well as unused area adjacent to the PMOS device in the top level.

To reduce such unused area and the overall footprint of a vertically stacked device, the present disclosure provides structures with a reduced number of dielectric structures 240 by forming at least one inactive transistor in the unused area and providing various routing options to allow rearrangement of both the active and the inactive transistors. Depending on the difference in the number of transistors on the top and the bottom levels, one or more of the dielectric structures 240 can be obviated from the vertically stacked device, thereby reducing the overall footprint of the device without impacting the performance of the device or violating design rules. In some embodiments, for each of the dielectric structures 240 obviated, a dummy transistor is formed in the level with a fewer number of functional transistors.

With respect to the device 400, instead of forming a third dielectric structure 240 to isolate the first FET 111 and the third FET 113 disposed in the bottom level, the third FET 113 is formed to share a common drain contact 135 with the first FET 111, and the fourth FET 114 is configured to be a dummy FET. Accordingly, the separation distance 402 is reduced from 4 CPP to 3 CPP, and the previously unused area laterally adjacent to the second FET 112 is occupied by the fourth FET 114. Such a rearrangement does not interfere with the performance of the three original functional transistors, namely the FETs 111-113, and does not violate the design rules of device placement. Additionally, the rearrangement and the presence of the dummy FET may improve the efficient utilization of chip area and reduce unused portion(s) of the chip area. The fourth FET 114 may be formed by utilizing different routing schemes as described below.

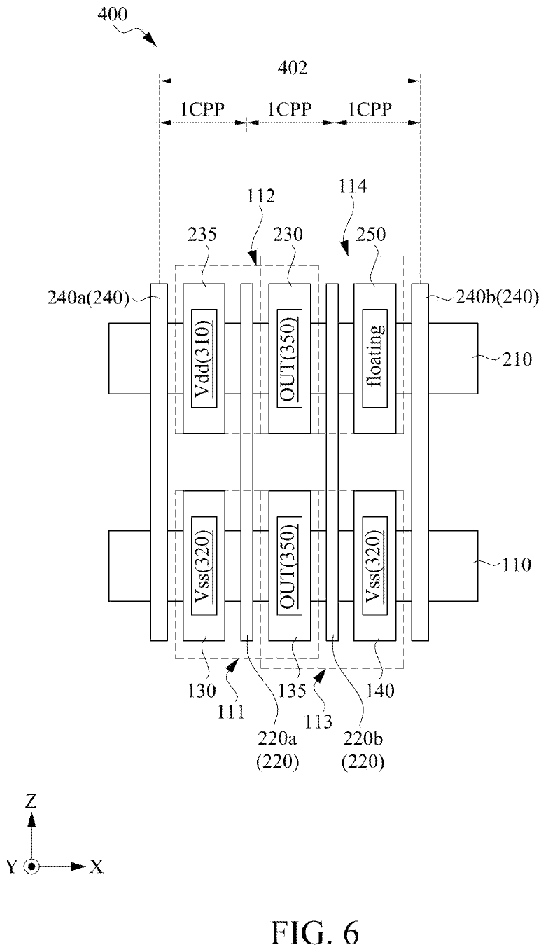

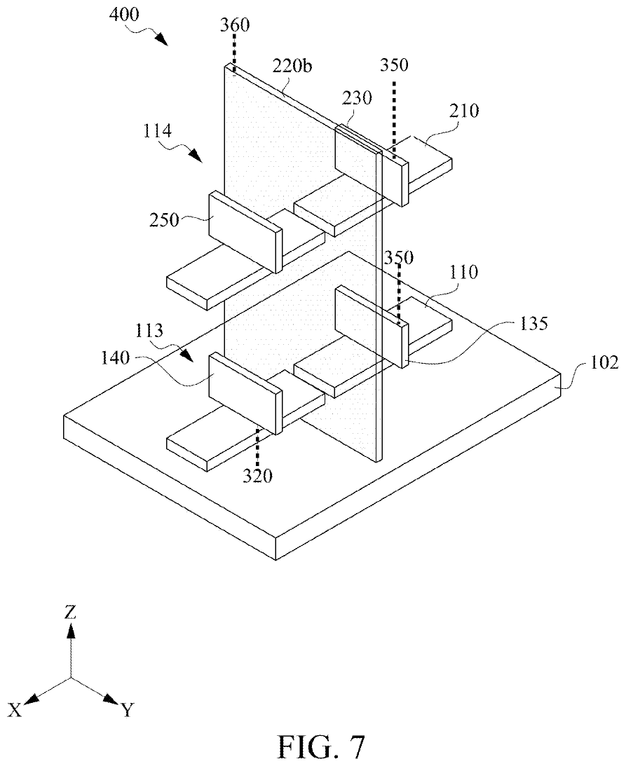

Referring to FIGS. 3-7 collectively, embodiments of the device 400 include the gate structures 220 each commonly engaging the channel regions in both the first semiconductor layer 110 and the second semiconductor layer 210, such that each gate structure 220 carries the same signal (i.e., be coupled to a single signal line, such as the signal line 360 depicted herein) for the corresponding vertically stacked FETs. In this regard, the fourth FET 114 is rendered a dummy FET by coupling the S/D contacts 230 and 250 to the same signal line 350, as depicted in FIGS. 3-5, according to some embodiments. Alternatively, referring to FIGS. 6 and 7, where FIG. 6 illustrates a cross-sectional view of an embodiment of the device 400 similar to that of FIG. 4 and FIG. 7 illustrates a perspective view of the device 400 depicting the second gate structure 220b, one of the S/D contacts 230 and 250 not shared with the adjacent second FET 112 (e.g., the drain contact 250) is configured as a floating contact, i.e., not coupled to any signal line, rendering the fourth FET 114 inactive.

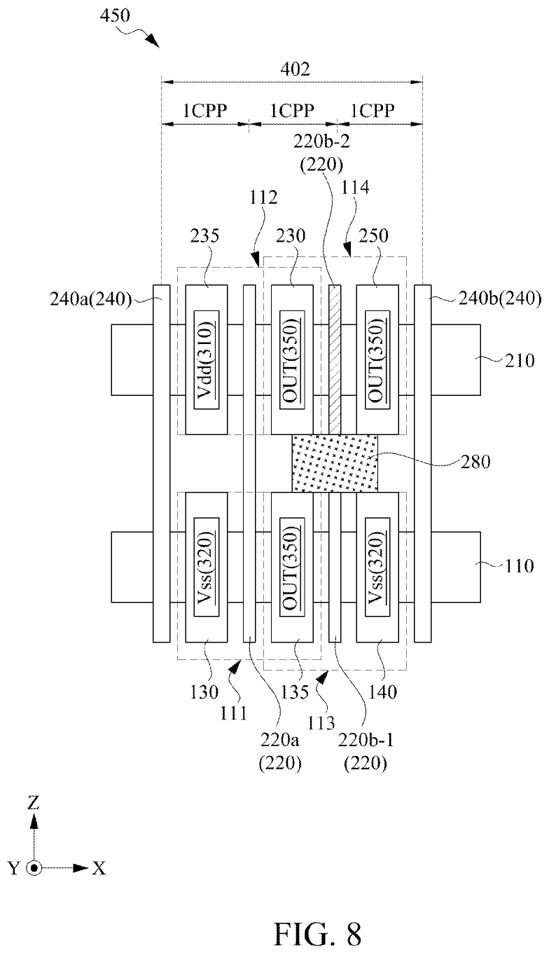

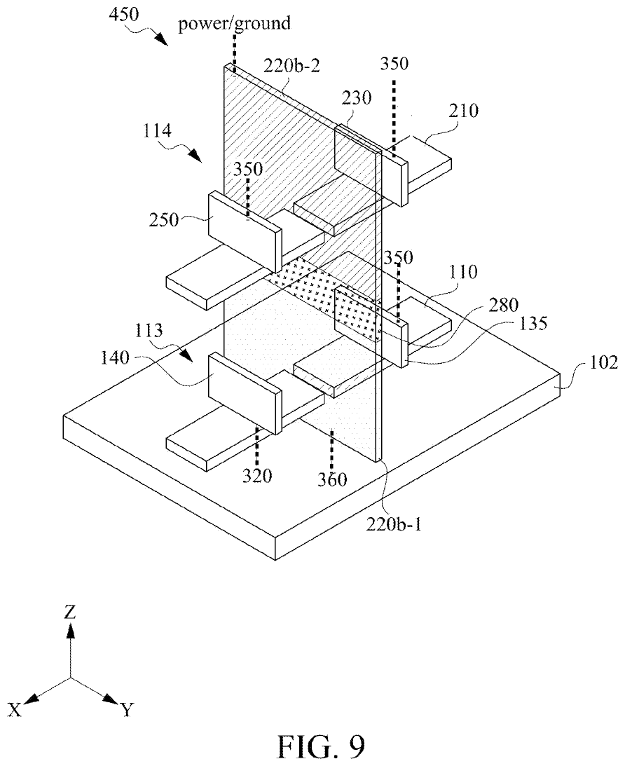

Referring to FIGS. 8-13 collectively, embodiments of a vertically stacked device (or device) 450, or portions thereof, are depicted. FIGS. 8, 10, and 12 each illustrate a cross-sectional view of the device 450 along a direction corresponding to line LL′ depicted in FIG. 2A, and FIGS. 9, 11, and 13 each illustrate a perspective view of the device 450 corresponding to FIGS. 8, 10, and 12, respectively.

The device 450 is substantially similar to the device 400 with the exception that the device 450 includes a gate isolation structure 280 configured to truncate or separate the gate structure second into a first (e.g., bottom or lower) portion 220b-1 and a second (e.g., top or upper) portion 220b-2 stacked over the first portion 220b-1. The gate isolation structure 280 may be substantially similar to the gate isolation structures 160 in composition. In the present embodiments, truncating the second gate structure 220b allows the first portion 220b-1 and the second portion 220b-2 to be coupled to different signal lines and/or power supply lines, which contrasts with the configuration of the device 400 depicted in FIGS. 3-7. For example, the first portion 220b-1 may be coupled to the signal line 360 as described above, while the second portion 220b-2 may be coupled to the power/ground (e.g., one of the power supply lines Vss 320 and Vdd 310), thereby rendering the fourth FET 114 a dummy FET independent of the routings of the S/D contacts 230 and 250. The coupling of the second portion 220b-1 to power/ground that renders the fourth FET 114 a dummy FET is referred to as a dummy tie-off structure.

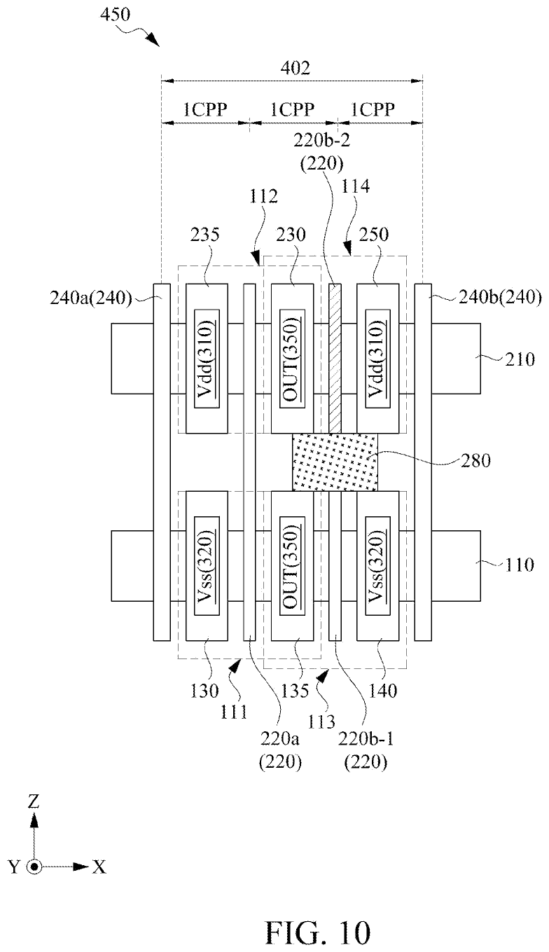

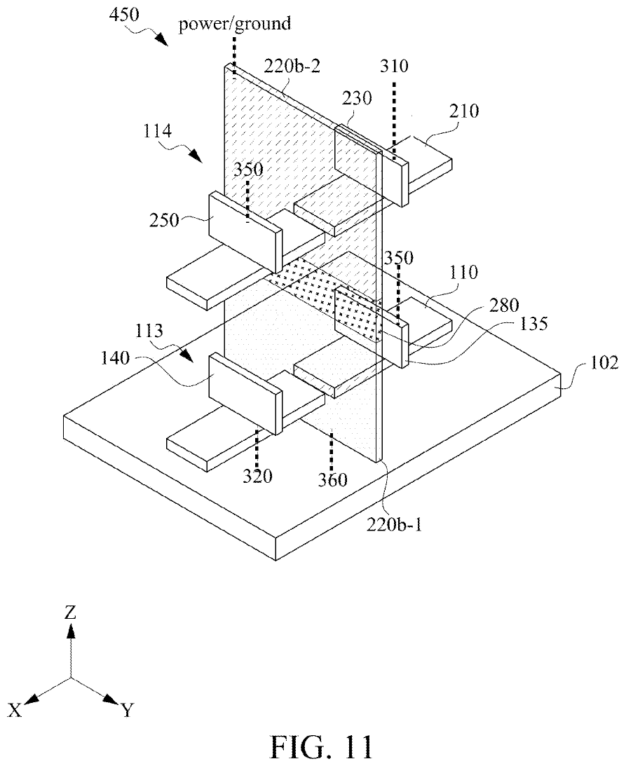

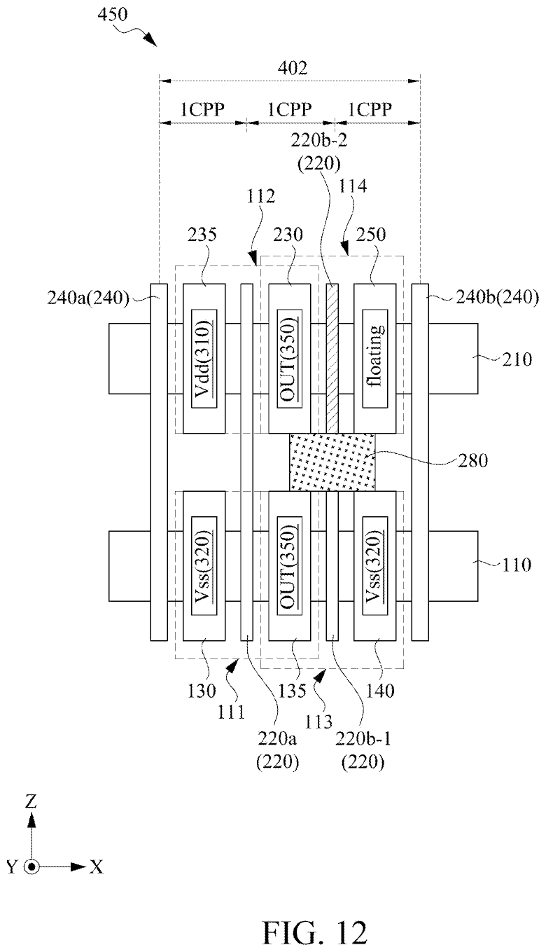

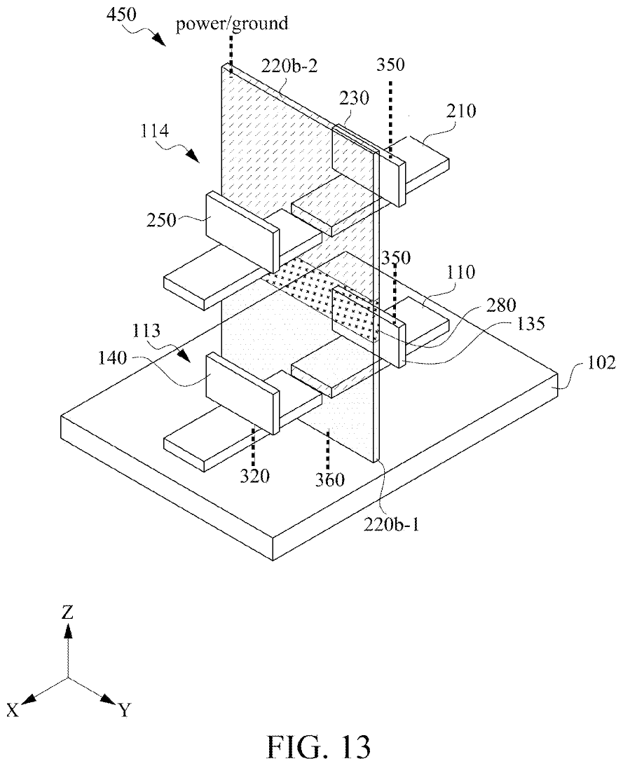

In some embodiments, referring to FIGS. 8 and 9, the S/D contacts 230 and 250 are coupled to the same signal line 350. In some embodiments, referring to FIGS. 10 and 11, the source contact 230 is coupled to the signal line 350 and the drain contact 250 is coupled to a different signal line or to a power supply line, such as the second power supply line Vdd 310. In some embodiments, referring to FIGS. 12 and 13, one of the S/D contacts 230 and 250 not shared with the adjacent second FET 112 (e.g., the drain contact 250) is configured as a floating contact.

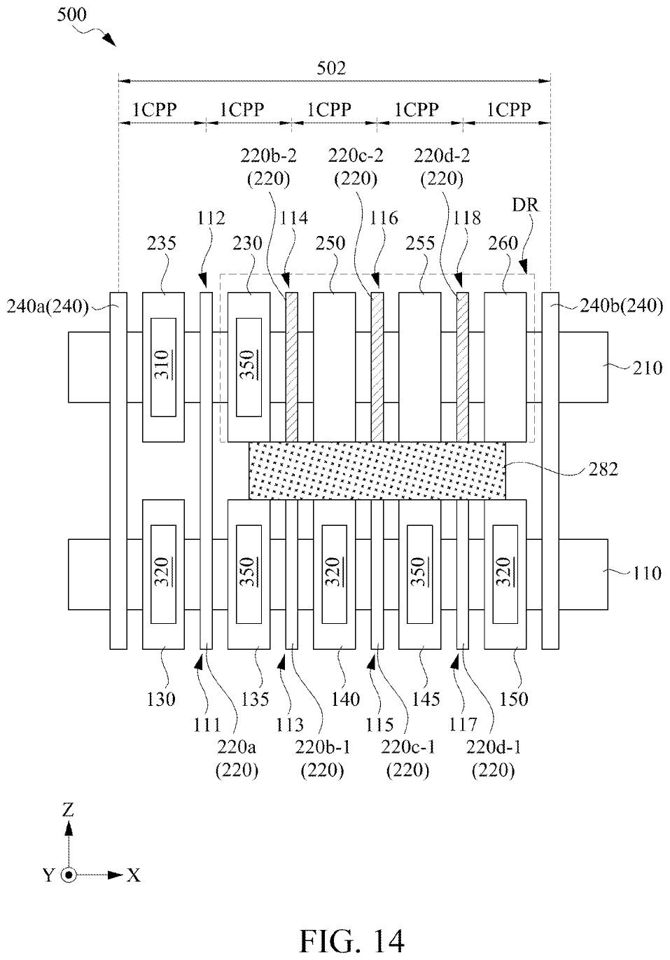

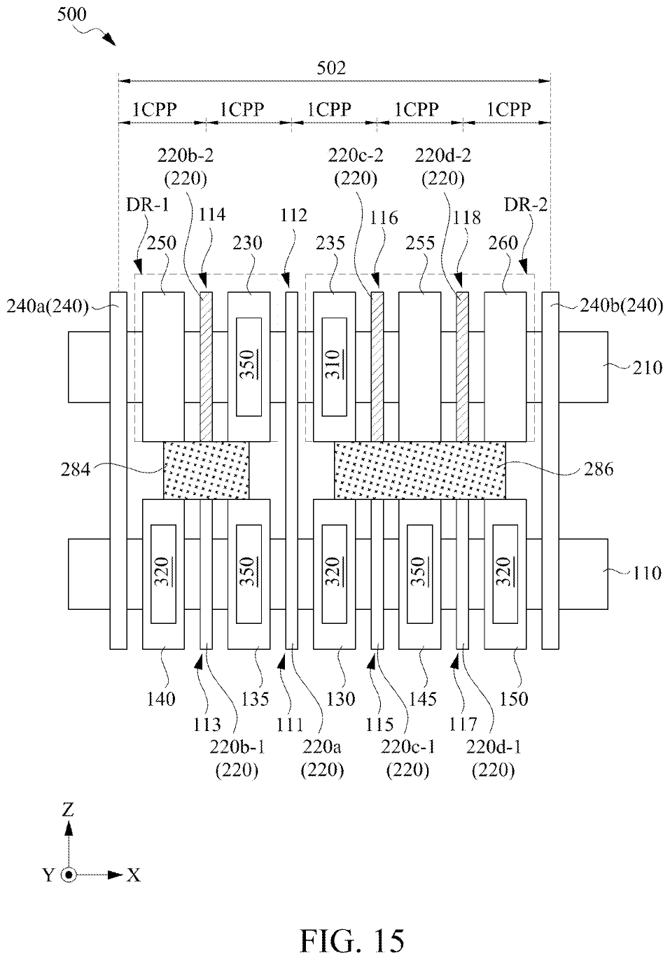

Referring to FIGS. 14 and 15, embodiments of a vertically stacked device (or device) 500, or portions thereof, are depicted. The device 500 is similar to the device 450 with the exception that the device 500 includes additional gate structures 220c and 220d extending parallel to the gate structures 220a and 220b, where the gate structures 220a-220d are collectively referred to as the gate structures 220 and disposed between the dielectric structures 240 along the first lateral direction. In some embodiments, a separation distance 502 between the dielectric structure 240a and 240b is approximately five (5) CPP, which corresponds to an area occupied by four (4) gate structures 220.

The gate structures 220c and 220d engage the channel regions of the semiconductor layers 110 and 210 to form a fifth FET 115 and a seventh FET 117, respectively, in the first semiconductor layer 110 (the bottom level), and a sixth FET 116 and an eighth FET 118, respectively, in the second semiconductor layer 210 (the top level). The FETs 115 and 117 are configured as functional FETs in the first semiconductor layer 110, similar to or the same as the FETs 111 and 113 described above. The FETs 116 and 118 are configured as dummy FETs in the second semiconductor layer 210, similar to or the same as the fourth FET 114 described above. In the present embodiments, two adjacent FETs 111, 113, 115, and 117 in the first semiconductor layer 110 share a common drain region, and two adjacent FETs 112, 114, 116, and 118 in the second semiconductor layer 210 share a common source region.

It is understood that the present disclosure does not limit the conductivity type of each of the FETs 111-118. For example, the FETs 111, 113, 115, and 117 disposed in the first semiconductor layer 110 may be of a conductivity type that is the same as or different from the FETs 112, 114, 116, and 118 disposed in the second semiconductor layer 210. If the FETs have different conductivity types, then the device 500 is rendered a CFET. In an example embodiment, the FETs 111, 113, 115, and 117 are configured as NMOS devices and the FETs 112, 114, 116, and 118 are configured as PMOS devices. It is further understood that the number of the gate structures 220 included in the device 500 is not intended to be limiting and may be adjusted based on device structures and/or design rules.

Referring to FIG. 14, the gate structures 220b-220d are truncated by a gate isolation structure 282 to form the first (bottom) portions 220b-1, 220c-1, and 220d-1 and second (top) portions 220b-2, 220c-2, and 220d-2, respectively. Because the second portions 220b-2, 220c-2, and 220d-2 are each coupled to power/ground, similar to the dummy tie-off structures depicted in FIGS. 8-13, the FETs 114, 116, and 118 are rendered inactive. Accordingly, the drain contact 250 of the fourth FET 114, S/D contacts 250 and 255 of the sixth FET 116, and S/D contacts 255 and 260 of the eighth FET 118 may be routed in any configuration similar to that depicted in each of FIGS. 8, 10, and 12. In this regard, routing options for such S/D contacts are not specifically labeled in FIG. 14. In one example, the S/D contacts 250, 255, and 260 may each be coupled to the same signal line as the source contact 230, such as the signal line 350, as depicted in FIG. 8. In another example, the S/D contacts 250-260 may each be coupled to a signal line different from the signal line 350 or to a power supply line, such as the second power supply line Vdd 310, as depicted in FIG. 10. In yet another example, the S/D contacts 250, 255, and 260 may each be a floating contact, as depicted in FIG. 12.

In some embodiments, referring to FIG. 14, the inactive FETs 114, 116, and 118 are disposed in a singular dummy region DR laterally adjacent to an active FET, e.g., the second FET 112. It is noted that, without rearranging the FETs in the device 500 and routing the S/D contacts of some of the FETs to render such FETs inactive, an additional dielectric structure 240 may be required to be placed between the source contact 230 (and the drain contact 135) and the gate structure second (the portions 220b-1 and 220b-2) to isolate the dummy region DR from the second FET 112, thereby increasing the separation distance 502 by one (1) CPP.

In some embodiments, referring to FIG. 15, the inactive FET 114 is disposed in a first dummy region DR-1 and the inactive FETs 116 and 118 are disposed in a second dummy region DR-2, where the dummy regions DR-1 and DR-2 are laterally separated by portions of the second FET 112. Similarly to the depicted embodiment in FIG. 14, without rearranging the FETs and routing the S/D contacts of some of the FETs to render such FETs inactive, one additional dielectric structure 240 may be required to be placed between the S/D contacts 230 (and the S/D contact 135) and the gate structure 220b (the portions 220b-1 and 220b-2), and another additional dielectric structure 240 may be required to be placed between the S/D contact 235 (and the S/D contact 130) and the gate structure 220c to isolate the second FET 112 from the dummy region DR-1 and the dummy region DR-2, respectively, thereby increasing the separation distance 502 by two (2) CPP.

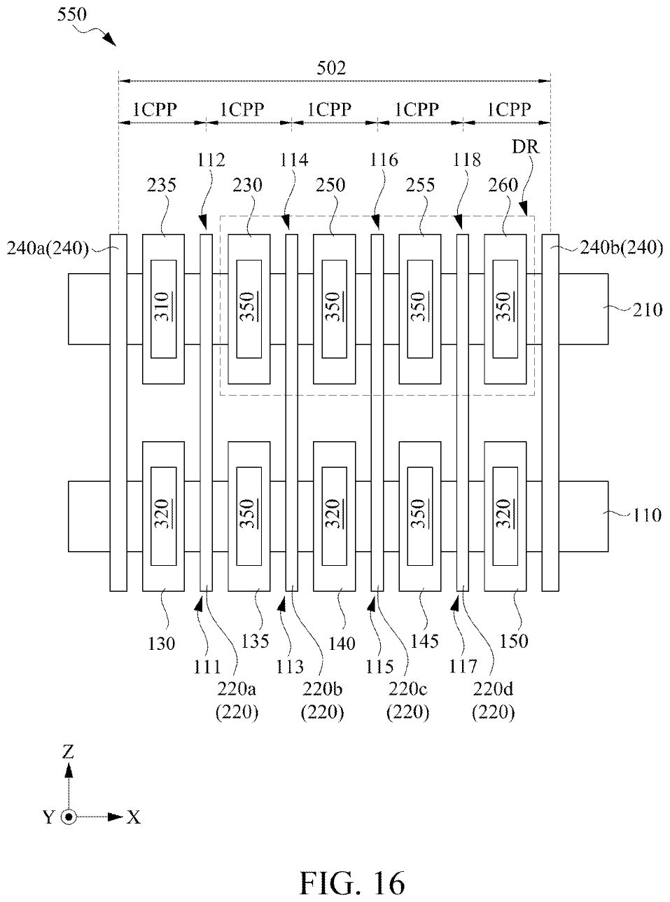

Referring to FIGS. 16-19, embodiments of a vertically stacked device (or device) 550, or portions thereof, are depicted. The device 550 is similar to the device 500 with the exception that the gate structures 220b, 220c, and 220d extend continuously along the vertical direction to engage with the semiconductor layers 110 and 210. As such, the resulting FETs 112, 114, 116, and 118 share a common gate structure with the FETs 111, 113, 115, and 117, respectively. The FETs 115 and 117 are configured as functional FETs in the first semiconductor layer 110, similar to or the same as the functional FETs 111 and 113 described above. The FETs 114, 116, and 118 are configured as inactive FETs in the second semiconductor layer 210, similar to or the same as the fourth FET 114 described above. In an example embodiment, the FETs 111-117 are configured as NMOS devices and the FETs 112-116 are configured as PMOS devices.

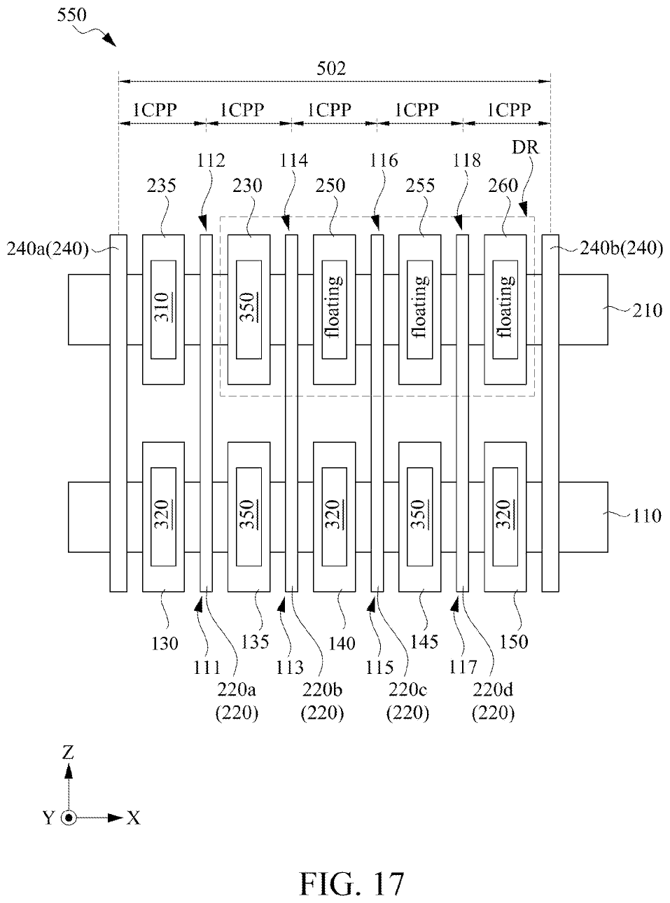

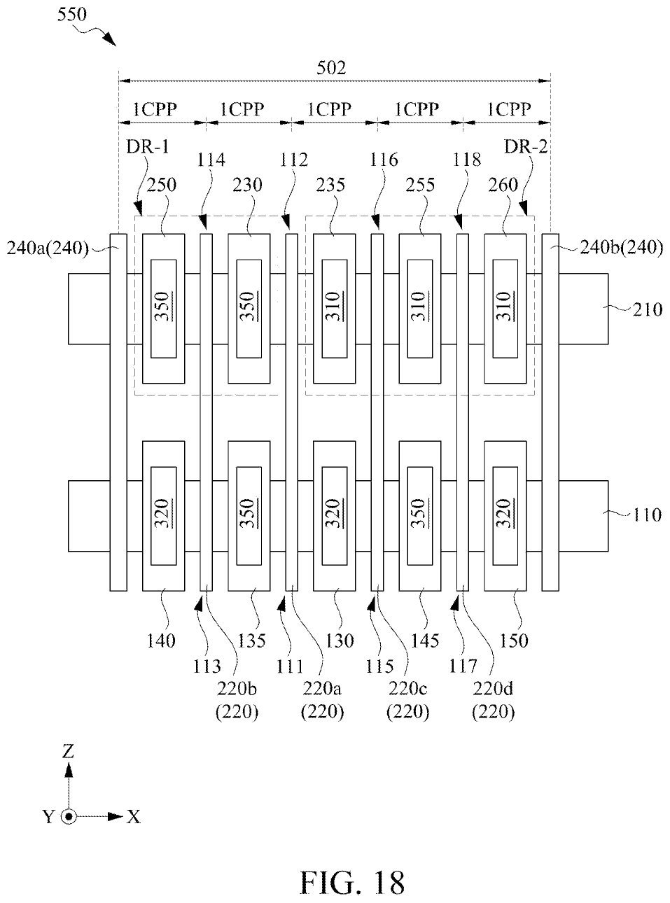

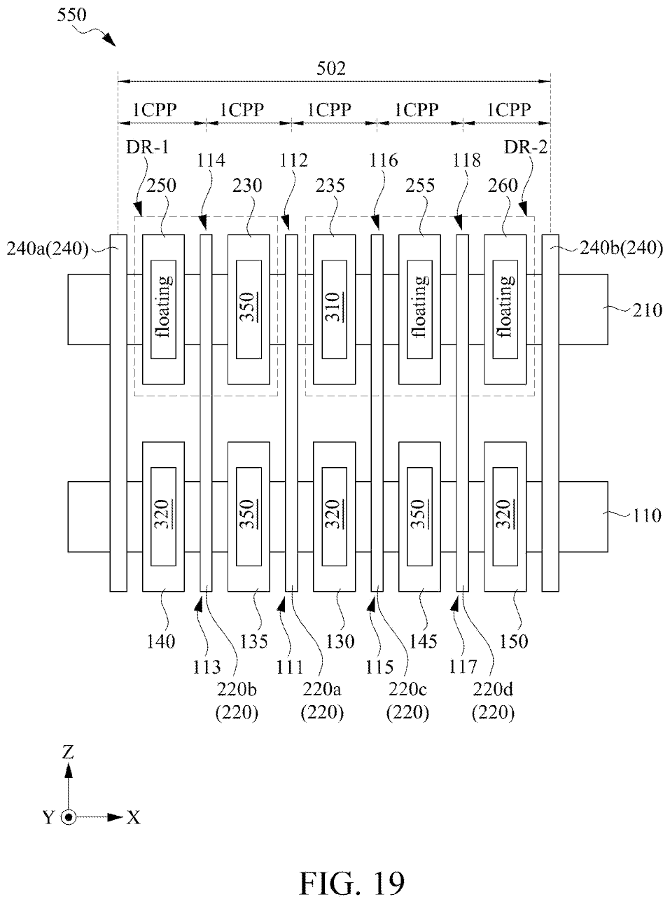

With the gate structures 220b, 220c, and 220d being shared by the active and the inactive FETs stacked vertically, the FETs 114, 116, and 118 may be rendered inactive by coupling their respective S/D contacts 250, 255, and 260 to the same signal line, e.g., the signal line 350, as depicted in FIGS. 16 and 18, which is similar to the device 400 in FIG. 3. Alternatively, the FETs 114. 116, and 118 may be rendered inactive by designating each of the S/D contacts 250, 255, and 260 as a floating contact, as depicted in FIGS. 17 and 19, which is similar to the device 400 in FIG. 6.

In some embodiments, referring to FIGS. 16 and 17, the inactive FETs 114-118 are disposed in the singular dummy region DR laterally adjacent to an active FET, e.g., the second FET 112. In some embodiments, referring to FIGS. 18 and 19, the inactive FET 114 is disposed in a first dummy region DR-1 and the inactive FETs 116 and 118 are disposed in a second dummy region DR-2, where the dummy regions DR-1 and DR-2 are laterally separated by portions of the second FET 112.

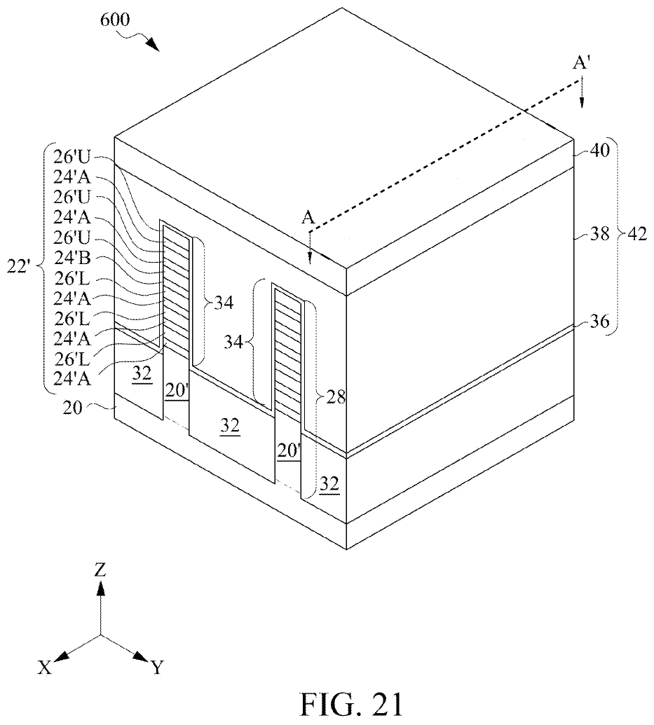

FIG. 20 illustrates a schematic perspective view of a vertically arranged CFET device 600 (hereafter referred to as the device 600) according to some embodiments of the present disclosure. The device 600 includes a multilayer structure 10 of a lower (or first) FET 10L and an upper (or second) FET 10U. The lower FET 10L is over a substrate 20 (depicted in FIGS. 21-25). The upper FET 10U is physically stacked over the lower FET 10L along the Z axis as depicted in FIG. 20. In this regard, the lower FET 10L is disposed between the substrate 20 and the upper FET 10U along the Z axis.

In some embodiments, the upper FET 10U and the lower FET 10L are of different conductivity types. In one such example, the upper FET 10U is a PMOS device and the lower FET 10L is an NMOS device, and the multilayer structure 10 is referred to as a P-on-N structure (e.g., a P-on-N CFET). In another example, the upper FET 10U is an NMOS device and the lower FET 10L is a PMOS device, and the multilayer structure 10 is referred to as a N-on-P structure (e.g., an N-on-P CFET). In some embodiments, the upper FET 10U and the lower FET 10L are of the same conductivity type, such as both are of n-type (forming an N-on-N structure) or both are of p-type (forming a P-on-P structure).

In some embodiments, the upper FET 10U and the lower FET 10L are each configured as a multi-channel device, such as a nanosheet FET, nanowire FET, or the like. In the example configuration depicted in FIGS. 20-25, the upper FET 10U and lower FET 10L are nanosheet FETs. Other device configurations may also be applicable to embodiments of the present disclosure. In some embodiments, the upper FET 10U and lower FET 10L have different semiconductor device configurations. For example, in some embodiments the lower FET 10L is a planar FET, while the upper FET 10U is a nanosheet FET.

The upper FET 10U includes a metal gate structure 82U, and S/D regions 62U on opposite sides of the metal gate structure 82U along an X-axis. The metal gate structure 82U extends, or is elongated, along a Y-axis. The X-axis, Y-axis, Z-axis are mutually transverse to each other. In some embodiments, the X-axis, Y-axis, Z-axis are mutually perpendicular to each other. The upper FET 10U further includes a channel region configured by nanosheets 26′U (also referred to as semiconductor layers 26U′) which extend along the X-axis and connect the S/D regions 62U. In some embodiments, the nanosheet 26′U corresponds to the second semiconductor layer 210 depicted in FIGS. 2-19. In the example configuration in FIG. 20, the upper FET 10U includes two nanosheets 26′U. Other numbers of nanosheets per transistor are within the scopes of various embodiments. The upper FET 10U includes a gate dielectric layer 78 extending around each of the nanosheets 26′U, and electrically isolating the metal gate structure 82U from the nanosheets 26′U. The metal gate structure 82U extends around the gate dielectric layer 78 and nanosheets 26′U in a configuration referred to as a gate-all-around (GAA) configuration. Other gate configurations are within the scopes of various embodiments.

The lower FET 10L includes a metal gate structure 82L, S/D regions 62L, a channel region configured by nanosheets 26′L (also referred to as semiconductor layers 26′L), and a gate dielectric layer 78 extending around each of the nanosheets 26′L. In some embodiments, the nanosheet 26′L corresponds to the first semiconductor layer 110 depicted in FIGS. 2-19. The metal gate structure 82L, S/D regions 62L, and nanosheets 26′L correspond to the metal gate structure 82U, S/D regions 62U, and nanosheets 26′U. The metal gate structure 82U, S/D regions 62U, and nanosheets 26′U correspondingly overlap the metal gate structure 82L, S/D regions 62L, and nanosheets 26′L along the Z axis. In the example configuration in FIG. 20, the S/D regions 62U, 62L are epitaxy structures of different conductivity types. For example, all S/D regions 62U are p-type doped epitaxy structures, and the S/D regions 62L are n-type doped epitaxy structures. In some embodiments, the S/D regions 62U, 62L are epitaxy structures of the same conductivity type.

The multilayer structure 10 further includes an intermediate layer 90 between the metal gate structure 82U and metal gate structure 82L. In some embodiments, the intermediate layer 90 includes a dielectric layer and is configured as a gate isolation structure (similar to the gate isolation structures 160 and 280) electrically isolating the metal gate structure 82U from the metal gate structure 82L, in a configuration referred to as an isolated gate configuration in which the metal gate structure 82U and metal gate structure 82L are controllable independently from each other.

As can be seen in the CFET devices provided herein, such as the devices 100, 200, 400, 450, 500, 550, and 600, one or more embodiments, the stacking of one FET (e.g., the second FET 12, the second FET 112, or the upper FET 10U) over another FET (e.g., the first FET 11, the first FET 111, or the lower FET 10L) saves about 50% of the required chip area, compared to other approaches without stacking of semiconductor devices. In some embodiments, it is possible to manufacturing an IC device comprising multiple device stacks by CFET processes, with little or no changes to the manufacturing processes.

FIG. 21 is a schematic perspective view of the device 600 in accordance with some embodiments. The device 600 comprises a plurality of device stacks formed on the substrate 20. In some embodiments, the substrate 20 is a semiconductor substrate. In some embodiments, the substrate 20 includes a single crystalline semiconductor layer on at least the surface of the substrate 20. The substrate 20 may have a composition similar to that described above with respect to the substrate of the device 200.

A multilayer structure 22′ is formed over the substrate 20. In FIG. 21, the multilayer structure 22′ is illustrated in a state after formation of fins, as described herein. The multilayer structure 22′ includes alternatingly arranged first semiconductor layers 24′A, 24′B and second semiconductor layers 26′U (i.e., the nanosheets 26U′ of FIG. 20), 26′L. The second semiconductor layers 26′U, 26′L correspond to the nanosheets described with respect to FIG. 20 and are referred to herein by the same reference numerals of the nanosheets, for simplicity. The first semiconductor layers 24′A, 24′B and the second semiconductor layers 26′U, 26′L include semiconductor materials having different etch selectivity and/or oxidation rates. For example, in some embodiments the first semiconductor layers 24′A, 24′B include SiGe, and the second semiconductor layers 26′U, 26′L include Si. In some embodiments, the first semiconductor layers 24′A, 24′B have different concentrations of Ge, resulting in different etch selectivity and/or oxidation rates therebetween. In some embodiments, the first and second semiconductor layers 24′A, 24′B, 26′U, 26′L are formed by a deposition process, such as epitaxy. For example, epitaxial growth of the layers of the multilayer structure 22′ is performed by a molecular beam epitaxy (MBE) process, a metalorganic chemical vapor deposition (MOCVD) process, and/or other suitable epitaxial growth processes.

Subsequent to the formation of the multilayer structure 22′, fins 28 are formed. Each fin 28 includes a substrate portion 20′ of the substrate 20, and a portion 34 of the multilayer structure 22′. The portion 34 of the multilayer structure 22′ is laternatively referred to as a stack of semiconductor layers 34. In some embodiments, the fins 28 are fabricated using suitable processes, such as double-patterning or multi-patterning processes. For example, in one or more embodiments, a sacrificial layer is formed over a substrate and patterned using a photolithography process. Spacers are formed alongside the patterned sacrificial layer using a self-aligned process. The sacrificial layer is then removed, and the remaining spacers are then used to pattern the fins 28 by etching the multilayer structure 22′ and the substrate 20. Example etch processes include, but are not limited to, dry etch, wet etch, reactive ion etch (RIE), and/or other suitable processes. In FIG. 21, two fins 28 are illustrated; however, the number of the fins is not limited to two. The fins 28 extend, or are elongated, along the X-axis.

In some embodiments, a shallow trench isolation (STI) 32 of an insulating material is formed over the substrate 20 and in trenches (not numbered) between the fins 28. For example, the insulating material is deposited over the substrate 20 and the fins 28. Example insulating materials of the STI 32 include, but are not limited to, silicon oxide, fluorine-doped silicate glass (FSG), silicon nitride, silicon oxynitride (SiON), silicon oxycarbonitride (SiOCN), silicon carbonitride (SiCN), a low-k dielectric material, or the like. The deposition of the insulating material includes a suitable method, such as low-pressure chemical vapor deposition (LPCVD), plasma enhanced CVD (PECVD) or flowable CVD (FCVD). Then, a planarization operation, such as a chemical mechanical polishing (CMP) process and/or an etch-back process, is performed such that the tops of the fins 28 are exposed from the insulating material. A portion of the insulating material between adjacent fins 28 is removed. The remaining portion of the insulating material configures the STI 32. The partial removal of the insulating material includes dry etch, wet etch, or the like.

In some embodiments, a sacrificial (or dummy) gate dielectric layer 36, a sacrificial (or dummy) gate electrode layer 38, and a mask structure 40 are deposited over the STI 32 and fins 28. In some embodiments, the sacrificial gate dielectric layer 36 comprises one or more layers of dielectric material, such as SiO2, SiN, a high-k dielectric material, and/or other suitable dielectric material. In some embodiments, the sacrificial gate dielectric layer 36 is deposited by a CVD process, a sub-atmospheric CVD (SACVD) process, a FCVD process, an atomic layer deposition (ALD) process, a physical vapor deposition (PVD) process, or other suitable process. In at least one embodiment, the sacrificial gate electrode layer 38 comprises polycrystalline silicon (polysilicon). In some embodiments, the mask structure 40 comprises a multilayer structure. In some embodiments, the sacrificial gate electrode layer 38 and the mask structure 40 are formed by one or more processes such as layer deposition, for example, CVD (including both LPCVD and PECVD), PVD, ALD, thermal oxidation, e-beam evaporation, or other suitable deposition techniques to obtain the device 600.

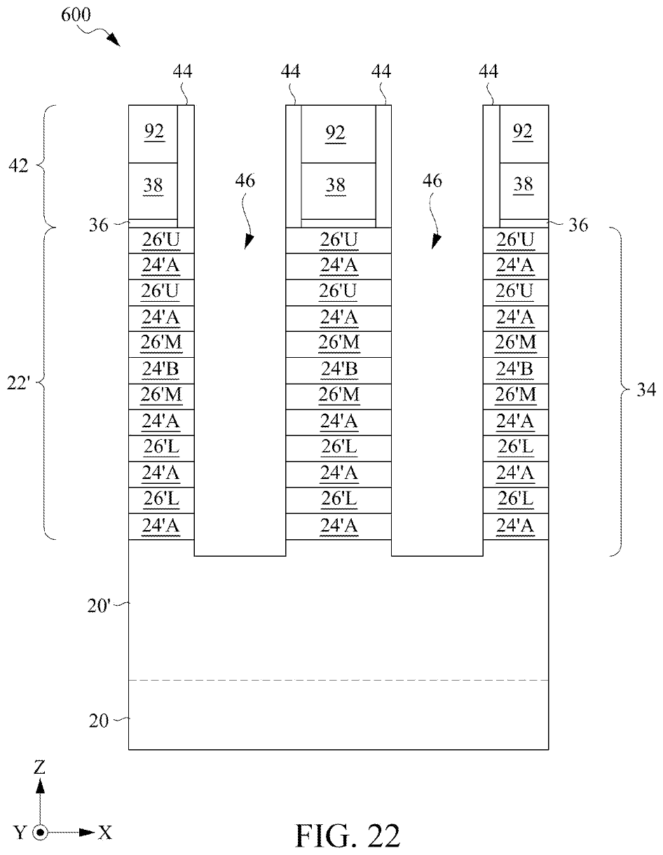

Referring to FIG. 22, sacrificial gate structures 42 are formed by one or more pattern and/or etch processes performed on the deposited sacrificial gate dielectric layer 36, sacrificial gate electrode layer 38, and mask structure 40. An example pattern process comprises a lithography process. An example etch process comprises dry etch (e.g., RIE), wet etch, other etch methods, and/or combinations thereof. Each sacrificial gate structure 42 comprises a portion of each of the sacrificial gate dielectric layer 36, sacrificial gate electrode layer 38, and mask structure 40. The sacrificial gate structures 42 extend, or are elongated, along the Y axis. In FIG. 1C, three sacrificial gate structures 42 are illustrated; however, the number of the sacrificial gate structures 42 is not limited to two.

Spacers 44 are formed on sidewalls of the sacrificial gate structures 42. For example, the spacers 44 are formed by first depositing a conformal layer that is subsequently etched back to form the spacers 44. The spacers 44 comprises a dielectric material, such as silicon oxide, silicon nitride, silicon carbide, silicon oxynitride, SiCN, silicon oxycarbide, SiOCN, and/or combinations thereof. In some embodiments, the spacers 44 comprise multiple layers.

Exposed portions of the stacks of semiconductor layers 34 of the fins 28 not covered by the sacrificial gate structures 42 and the spacers 44 are selectively removed, e.g., by one or more suitable etch processes, such as dry etch, wet etch, or a combination thereof, to form trenches 46. In FIG. 22, a lower most one of the second semiconductor layers 26′U and an uppermost one of the second semiconductor layers 26′L are designated as middle second semiconductor layers 26′M which sandwich therebetween a middle first semiconductor layer 24′B. The middle second semiconductor layers 26′M and the middle first semiconductor layer 24′B are not configured to form channel regions of the upper FET 10U and lower FET 10L. Edge portions of the first semiconductor layers 24′A, 24′B and second semiconductor layers 26′U, 26′L, 26′M are exposed in the trenches 46. The trenches 46 also expose portions of the substrate portion 20′ and obtain the device 600 as depicted in FIG. 22.

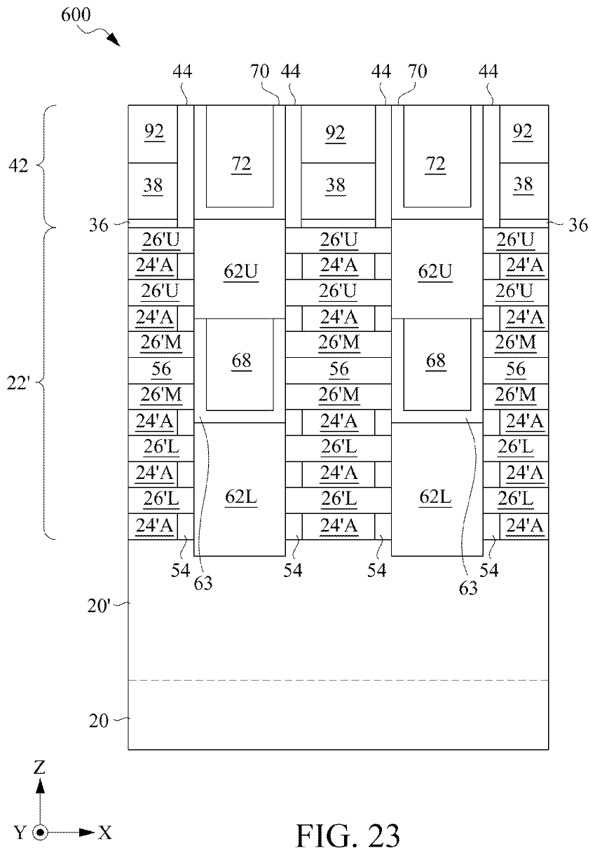

Referring to FIG. 23, the exposed edge portions of the first semiconductor layers 24′A are removed. In some embodiments, the removal comprises a selective wet etch process. The selective wet etch process further completely (or substantially completely) removes the first semiconductor layer 24′B in the middle of the stack of semiconductor layers 34. For example, in embodiments where the first semiconductor layers 24′A, 24′B include SiGe, and the second semiconductor layers 26′U, 26′L, 26′M include Si, a selective wet etch is configured to etch the first semiconductor layer 24′B at a highest etch rate, the first semiconductor layers 24′A at a second highest etch rate, and the second semiconductor layers 26′U, 26′L, 26′M at a slowest etch rate. As a result, the exposed edge portions of each of the first semiconductor layers 24′A and an entirety (or substantially an entirety) of each of the first semiconductor layer 24′B are removed, whereas the second semiconductor layers 26′U, 26′L, 26′M are substantially unchanged.

A dielectric material is deposited over and into the spaces created by the removal of the first semiconductor layer 24′B and the partial removal of the edge portions of the first semiconductor layers 24′A. The dielectric material filling in the spaces created by the partial removal of the edge portions of the first semiconductor layers 24′A configures inner spacers 54. The dielectric material filling in the space created by the removal of the first semiconductor layer 24′B configures an inner isolation structure 56. Examples of the dielectric material forming the inner spacers 54 and inner isolation structure 56 include, but are not limited to, a low-k dielectric material, such as SiO₂, SiN, SiCN, SiOC, or SiOCN, or a high-k dielectric material, such as HfO₂, ZrOx, ZrAlOx, HfAlOx, HfSiOx, AlOx, or other suitable dielectric material. In some embodiments, the inner spacers 54 and inner isolation structure 56 comprise different dielectric materials. In an example process, the inner spacers 54 and inner isolation structure 56 are formed by depositing a conformal layer of the dielectric material, using a conformal deposition process, such as ALD, followed by an anisotropic etching to remove portions of the conformal layer other than the inner spacers 54 and inner isolation structure 56.

S/D regions 62L are formed over, and in contact with, the exposed portions of the substrate portions 20′, and exposed edge portions of the second semiconductor layers 26′L. In the example configuration in FIG. 23, the S/D regions 62L include epitaxy structures and are therefore alternatively referred to as S/D epitaxy structures 62L. In some embodiments, the S/D epitaxy structures 62L includes one or more layers of Si, SiP, SiC and SiCP to configure an n-type bottom semiconductor device, i.e., the lower FET 10L. In some embodiments, the S/D epitaxy structures 62L include one or more layers of Si, SiGe, Ge to configure a p-type bottom semiconductor device. Example epitaxial growth processes for growing the S/D epitaxy structures 62L include, but are not limited to, CVD, ALD, MBE. In some embodiments, S/D epitaxy structures 62L are grown to a height above the uppermost second semiconductor layer 26′L, and then top portions of the S/D epitaxy structures 62L are partially removed, e.g., by a dry etch or wet etch, so that upper surfaces of the remaining S/D epitaxy structures 62L are at a level of the uppermost first semiconductor layer 24′A immediately under the lower middle second semiconductor layer 26′M, as illustrated in FIG. 23.

A liner 63 is formed at least over the upper surfaces of the S/D epitaxy structures 62L, and exposed side faces of the middle second semiconductor layers 26′M, inner isolation structure 56. In some embodiments, the liner 63 comprises Si. In an example process, the liner 63 is a conformal layer formed by a conformal process, such as an ALD process.

A dielectric material 68 is formed over the liner 63 and over the S/D epitaxy structures 62L. In some embodiments, the dielectric material 68 comprises the same material as the STI 32 and/or is formed by the same method as the STI 32. The liner 63 and dielectric material 68 are removed outside the trenches 46, and partially removed inside the trenches 46, e.g., by a dry etch or wet etch. As a result, upper surfaces of the liner 63 and dielectric material 68 are at a level of the lowermost first semiconductor layer 24′A immediately above the upper middle second semiconductor layer 26′M, as illustrated in FIG. 23. The liner 63 and dielectric material 68 configure an isolation structure between the S/D regions 62L and S/D regions 62U to be subsequently formed thereover.

S/D regions 62U are formed over, and in contact with, the upper surfaces of the liner 63 and dielectric material 68, and exposed edge portions of the second semiconductor layers 326U. In the example configuration in FIG. 23, the S/D regions 62U comprise epitaxy structures and are sometimes referred to as S/D epitaxy structures 62U. In some embodiments,

In some embodiments, the S/D epitaxy structures 62U are of the same conductivity type as the S/D epitaxy structures 62L. In some embodiments, the S/D epitaxy structures 62U comprise the same material and/or are manufactured by the same manufacturing processes as the S/D epitaxy structures 62L. In at least one embodiment, the S/D epitaxy structures 62U have the same configuration, e.g., the same size, shape, height, material, as the S/D epitaxy structures 62L. In an example, where the S/D epitaxy structures 62L comprise one or more layers of Si, SiP, SiC and SiCP to configure an N-type bottom semiconductor device, the S/D epitaxy structures 362U comprise one or more layers of Si, SiP, SiC and SiCP to configure an N-type top semiconductor device. In another example, where the S/D epitaxy structures 62L comprise one or more layers of Si, SiGe, Ge to configure a P-type bottom semiconductor device, the S/D epitaxy structures 362U comprise one or more layers of Si, SiGe, Ge to configure a P-type top semiconductor device.

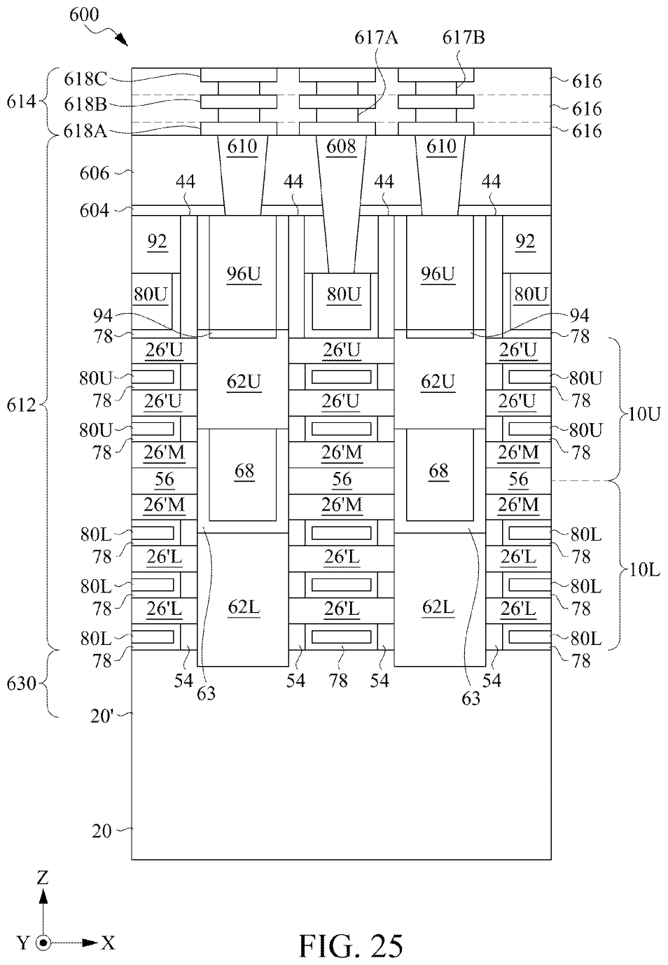

In some embodiments, S/D epitaxy structures 62U are grown to a height above the sacrificial gate dielectric layer 36, and then top portions of the S/D epitaxy structures 62U are partially removed, e.g., by a dry etch or wet etch, so that upper surfaces of the remaining S/D epitaxy structures 62U are at a level of the sacrificial gate dielectric layer 36, as illustrated in FIG. 25. This is an example, and a height of the S/D epitaxy structures 62U is controllable depending on application and/or process requirements.

A contact etch stop layer (CESL) 70 is formed over the S/D epitaxy structures 62U. Example materials of the CESL 70 include, but are not limited to, silicon nitride, silicon carbon nitride, silicon oxynitride, carbon nitride, silicon oxide, silicon carbon oxide, the like, or a combination thereof. The CESL 70 is formed by CVD, PECVD, ALD, or any suitable deposition technique.

An interlayer dielectric (ILD) layer 72 is formed over the CESL 70. Example materials of the ILD layer 72 include, but are not limited to, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 72 is deposited by a PECVD process or other suitable deposition technique to obtain the device 600 as depicted in FIG. 23.

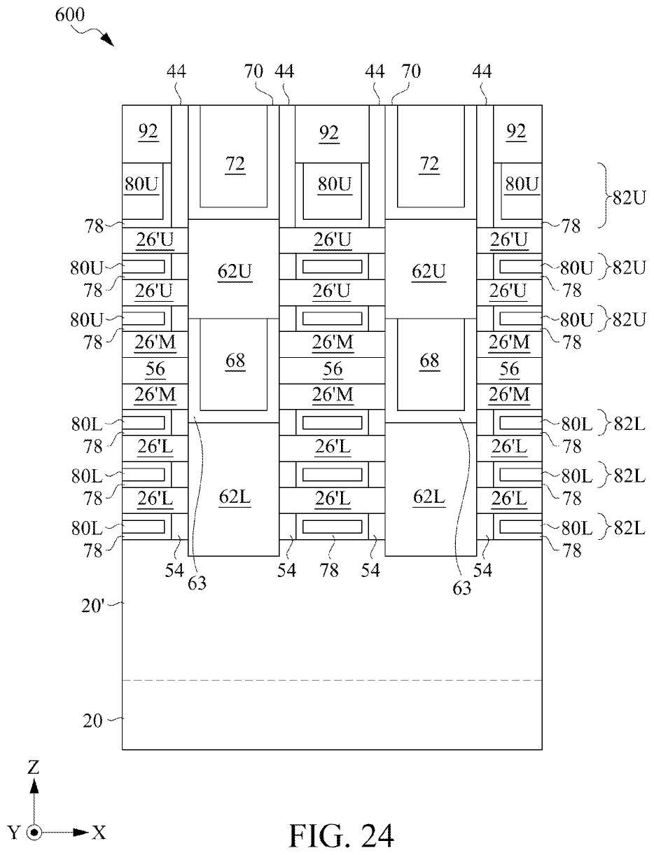

Referring to FIG. 24, a planarization process, such as a CMP process, is performed to remove the mask structure 40 and expose the sacrificial gate electrode layer 38. The planarization process also removes portions of the ILD layer 72 and the CESL 70.

The exposed sacrificial gate electrode layer 38 and the sacrificial gate dielectric layer 36 are removed, e.g., by one or more suitable processes, such as dry etch, wet etch, or a combination thereof.

Next, the first semiconductor layers 24′A are removed, e.g., by any suitable processes, such as dry etch, wet etch, or a combination thereof. The removal of the first semiconductor layers 24′A exposes the inner spacers 54 and the second semiconductor layers 26′U, 26′L, and creates spaces between and around exposed portions of the second semiconductor layers 26′U, 26′L not covered by the inner spacers 54. The exposed portions of the second semiconductor layers 26′U, 26′L configure the nanosheets 26′U, 26′L described with respect to FIG. 20. The middle second semiconductor layers 26′M and inner isolation structure 56 are covered by the liner 63 and dielectric material 68 and are substantially unaffected by the removal of the first semiconductor layers 24′A.

A gate dielectric layer 78 is formed over and around each of the nanosheets 26′U, 26′L. In some embodiments, the gate dielectric layer 78 includes the same material as the sacrificial gate dielectric layer 36. In some embodiments, the gate dielectric layer 78 comprises a high-k dielectric material. In some embodiments, the gate dielectric layer 78 is formed by a conformal process, such as an ALD process.

A gate electrode is formed over and around the gate dielectric layers 78, and the nanosheets 26′U, 26′L. Gate electrode 80U surrounds each of the nanosheets 26′U, i.e., is disposed above the inner isolation structure 56, and is configured to form each upper metal gate structure 82U (e.g., upper MG 82U). Gate electrode 80L surrounds each of the nanosheets 26′L, i.e., is disposed below the inner isolation structure 56, is configured to form each lower metal gate structure 82L (e.g., lower MG 82L). In some embodiments, the gate electrodes 80U and 80L include, but are not limited to, polysilicon, Al, Cu, Ti, Ta, W, Co, Mo, nickel silicide, cobalt silicide, TaN, TiN, WN, WCN, TiAl, TiTaN, TiAlN, TaN, TaCN, TaC, TaSiN, metal alloys, the like, or combinations thereof. In some embodiments, the gate electrode material includes one or more work function metals. Example processes for depositing the gate electrode material include, but are not limited to, PVD, CVD, ALD, electro-plating, or other suitable methods.

In some embodiments, each of the gate electrode 80U and gate electrode 80L is configured to form a corresponding GAA structure, and the upper gate structures 82U and the lower gate structures 82L are physically and electrically separated from each other by the middle second semiconductor layers 26′M and inner isolation structure 56. In some embodiments, a combination of the middle second semiconductor layers 26′M and inner isolation structure 56 corresponds to the intermediate layer 90 being a dielectric material in an isolated gate configuration. The formation of the gate electrode 80U and gate electrode 80L completes the formation of the upper FET 10U and the lower FET 10L in a front-end-of-line (FEOL) fabrication.

In the present embodiments, the upper FET 10U corresponds to any of the second FET 112, the fourth FET 114, the sixth FET 116, and the eighth FET 118 in structure and electrical connection, and the lower FET 10U corresponds to any of the first FET 111, the third FET 113, the fifth FET 115, and the seventh FET 117, as depicted in FIGS. 2-19.

An ILD layer 92 similar to the ILD layer 72 is deposited over the upper gate structures 82U, and a planarization process, such as a CMP, is performed to obtain the device 600 as depicted in FIG. 24.

Referring to FIG. 25, openings are formed in the ILD layer 72 to expose the S/D epitaxy structures 62U. A silicide layer 94 is formed over the exposed S/D epitaxy structures 62U, and then S/D contacts 96U are form in each opening and over the silicide layer 94. S/D contacts are alternatively referred to as metal-to-device (MD) contacts. In the present embodiments, the S/D contacts 96U correspond to source contacts and drain contacts 130, 135, 140, 230, 235, and 250 as depicted in FIGS. 2-19. Example materials of the S/D contacts 96U include, but are not limited to, Ru, Mo, Co, Ni. W, Ti, Ta, Cu, Al, TiN and TaN. The S/D contacts 96U are formed by any suitable process, such as PVD, ECP, or CVD.

Dielectric layers 604, 606 are deposited over the S/D contacts 96U and ILD layer 92. Various vias 608, 610 are formed by etching via openings in the dielectric layers 604, 606 and ILD layer 92, and then filling the via openings with a conductive material, such as a metal. A via over and in electrical contact with an MD contact is sometimes referred to as via-to-device (VD) via. A via over and in electrical contact with a gate is sometimes referred to as via-to-gate (VG) via, which may alternatively be referred to as a gate contact. In the example configuration in FIG. 25, the via 608 is a VG via which is over the metal gate structure 82U, and the vias 610 are VD vias correspondingly over the MD contacts 96U. VG and VD vias for bottom semiconductor devices are sometimes correspondingly referred to as BVG and BVD vias.

In some embodiments, the formation of the VG, VD vias completes a middle-end-of-line (MEOL) fabrication. The resulting device 600 including various semiconductor devices (e.g., the upper FET 10U and the lower FET 10L) formed over a frontside (or upper side) of the substrate 20 and the corresponding MD contacts, VG and VD vias is obtained. The MEOL fabrication is followed by a back-end-of-line (BEOL) fabrication to provide routing for the semiconductor devices.

The BEOL fabrication includes forming an MLI structure 614 over the VD vias 610, VG vias 608. The MLI structure 614 includes a plurality of metallization layers 618A, 618B, and 618C and via layers 617A and 617B sequentially and alternatingly formed over the VD vias 610, VG vias 608. In some embodiments, the MLI structure 614 may be similar to the MLI structure 305 depicted in FIG. 2A. The MLI structure 614 further includes various interlayer dielectric (ILD) layers 616 in which the metal layers and via layers are embedded. The metal layers and via layers of the MLI structure 614 are configured to electrically couple various semiconductor devices, or circuits, of the device 600 with each other, and/or with external circuitry.

In some embodiments, one or more of the metallization layers of the MLI structure 614, including the metallization layers 618A, 618B, and 618C, are configured to provide power supply lines, which correspond to the power supply lines Vdd 310 and Vss 320, and signal lines, which correspond to the signal lines 350 and 360, as described in detail above with respect to the devices 200, 400, 500, and 550. In this regard, each of these components of the MLI structure 614 are configured to electrically couple to one or more of the FETs of the device 600, such as the upper FET 10U and the lower FET 10L, in a manner similar to that of the respective electrical connection between the components of the MLI structure 305 and the FETs depicted in FIGS. 2-19, such as the first FET 111, the second FET 112, the third FET 113, and the fourth FET 114, each of which corresponding to the upper FET 10U, and the fifth FET 115, the sixth FET 116, the seventh FET 117, and the eighth FET 118, each of which corresponding to the lower FET 10L.

In the MLI structure 614, the bottommost metallization layer 618A immediately over and in electrical contact with the VD vias 610, VG vias 608 is an M0 layer, a next metallization layer 618B immediately over the M0 layer is an M1 layer, a next metallization layer 618C immediately over the M1 layer is an M2 layer, or the like. Conductive patterns in the M0 layer are referred to as M0 conductive patterns, conductive patterns in the M1 layer are referred to as M1 conductive patterns, or the like. A via layer Vn is arranged between and electrically couple the Mn layer and the Mn+1 layer, where n is an integer from zero and up. For example, the via layer 617A is a V0 layer which is the bottommost via layer arranged between and electrically couple the M0 metallization layer 618A and the M1 metallization layer 618B. The next via layer 617B is a V1 layer which is the via layer arranged between and electrically couple the M1 metallization layer 618B and the M2 metallization layer 618C. Vias in the V0 layer are referred to as V0 vias, vias in the V1 layer are referred to as V1 vias, or the like. Additional operations may be performed after forming the M2 metallization layer 618C and the via layer 617B. For simplicity, additional metal layers and via layers formed over the metallization layer 618C and the via layer 617B are not fully illustrated in FIG. 25.

In at least one embodiment, one or more advantages described herein are achievable by IC devices comprising device stacks described with respect to FIG. 20, and/or IC devices fabricated by processes described with respect to FIGS. 21-25. Although the described fabricating processes include formation of nanosheet devices in one or more embodiments, other types of devices, e.g., nanowire, FinFET, planar, or the like, are within the scopes of various embodiments. The described fabricating processes and/or orders of operations are examples. Other fabricating processes and/or orders of operations are within the scopes of various embodiments.

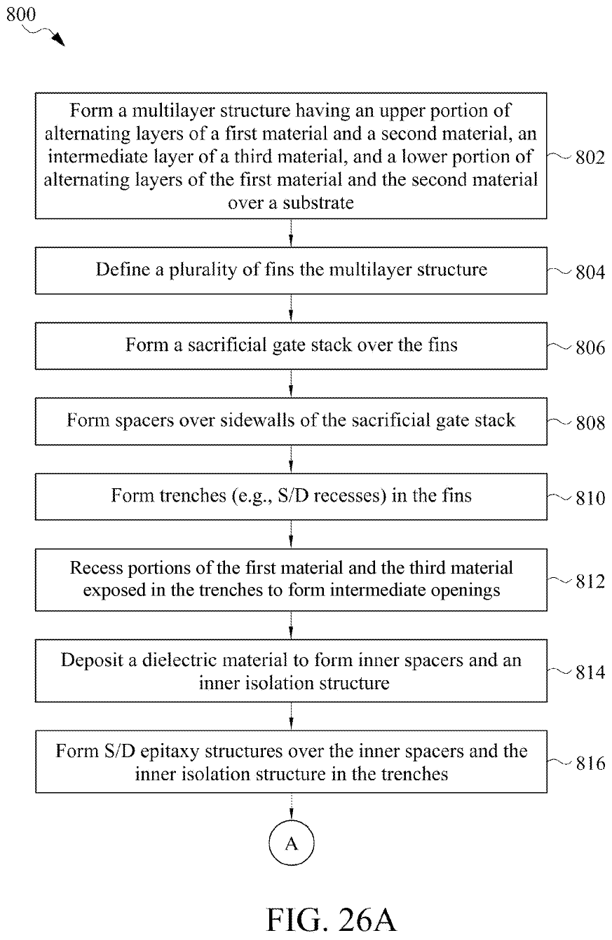

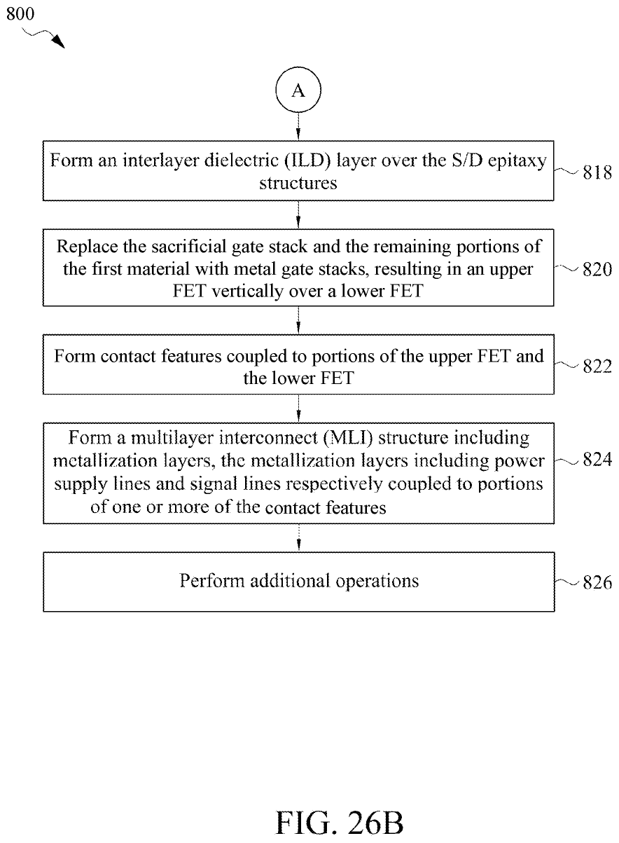

FIGS. 26A and 26B collectively illustrates a flowchart of a method 800 to form a device according to one or more embodiments of the present disclosure. For example, at least some of the operations of the method 800 can be used to form a CFET device, such as one of the devices 100, 200, 400, 450, 500, 550, and 600. It is noted that the method 800 is merely an example, and is not intended to limit the present disclosure. Accordingly, it is understood that additional operations may be provided before, during, and after the method 800, and that some other operations may only be briefly described herein. In some embodiments, operations of the method 800 may be associated with perspective and cross-sectional views of the device 600 at various fabrication stages as shown in FIGS. 21-25, which are discussed in detail above.

Referring to FIG. 21, a multilayer structure (e.g., the multilayer structure 22′) of alternating first semiconductor layers (e.g., the first semiconductor layers 24′A, 24′B) and second semiconductor layers (e.g., the second semiconductor layers 26′U, 26′L) is formed over a substrate (e.g., the substrate 20) at operation 802. Specifically, the multilayer structure includes an upper portion having alternating first semiconductor material (e.g., the first semiconductor layers 24′A) and second semiconductor material (e.g., the second semiconductor layers 26′U); a lower portion having alternating first semiconductor material and second semiconductor material (e.g., the second semiconductor layers 26′L); and an intermediate layer of a third semiconductor material (e.g., the first semiconductor layer 24′B) different from the first semiconductor material and the second semiconductor material in composition. The intermediate layer of the third semiconductor material is interleaved between two layers (e.g., the second semiconductor layers 26′M) of the second semiconductor material that are configured as dummy layers.

A plurality of fins (e.g., the fins 28; also referred to as active regions) are defined in the multilayer structure at operation 804 by one or more etching processes. An STI (e.g., the STI 32) may be formed over the substrate and between the fins. Subsequently, still referring to FIG. 21, a sacrificial gate structure (e.g., the sacrificial gate structure 42) including a sacrificial gate dielectric layer (e.g., the sacrificial gate dielectric layer 36), a sacrificial gate electrode layer (e.g., the sacrificial gate electrode layer 38), and a mask structure (e.g., the mask structure 40) is formed over the fins at operation 806.

Referring to FIG. 22, corresponding spacers (e.g., the spacers 44) are then formed over sidewalls of the sacrificial gate structure 42 at operation 808. Trenches (e.g., the trenches 46; also referred to as S/D recesses) are formed in each of the fins at operation 810. Exposed portions of the first semiconductor material (e.g., the exposed edge portions of each of the first semiconductor layers 24A′) and an entirety of the third semiconductor material (e.g., the first semiconductor layer 24B′) in the trenches are then recessed to form intermediate openings (not depicted herein) at operation 812. The second semiconductor material (e.g., the second semiconductor layers 26′U, 26′L) remain substantially intact during the recessing at operation 812. Subsequently, a dielectric material is deposited in the trenches to form inner spacers (e.g., the inner spacers 54) and an inner isolation structure (e.g., the inner isolation structure 56; also referred to as a gate isolation structure) at operation 814.

Referring to FIG. 23, lower S/D epitaxy structures (e.g., the S/D epitaxy structures 62L) and upper S/D epitaxy structure (e.g., the S/D epitaxy structures 62U), collectively referred to as S/D epitaxy structures, are formed over the inner spacers and the inner isolation structures in the trenches at operation 816. In some embodiments, a liner (e.g., the liner 63) and a dielectric material (e.g., the dielectric material 68) are formed over upper surfaces of the lower S/D epitaxy structures before forming the upper epitaxy structures. An ILD layer (e.g., the ILD layer 72) is then formed over the S/D epitaxy structures at operation 818. In some embodiments, a CESL (e.g., the CESL 70) is formed over the S/D epitaxy structures before forming the ILD layer. A CMP process is subsequently performed to planarize the CESL and/or the ILD layer.

Subsequently, referring to FIG. 24 the sacrificial gate structure and the remaining portions of the first semiconductor layers (e.g., the remaining portions of the first semiconductor layers 24A′) are replaced with metal gate structures that each include a gate dielectric layer (e.g., the gate dielectric layer 78) and a gate electrode (e.g., the gate electrode 80U and the gate electrode 80L) at operation 820. In the depicted embodiment, the gate structures formed in the upper portion of the device 600, i.e., above the inner isolation structure 56, are referred to as upper gate structures (e.g., the upper gate structures 82U) that each include the gate electrode 80U, and the gate structures formed in the lower portion of the device 600, i.e., below the inner isolation structure 56, are referred to as lower gate structures (e.g., the lower gate structures 82L) that each include the gate electrode 80L.

Thereafter, referring to FIG. 25, various contact features are formed at operation 822. The contact features include frontside S/D contacts (e.g., the S/D contacts 96U) electrically coupled to at least some of the S/D epitaxy structures (e.g., the S/D epitaxy structures 62U in the upper portion of the device 600) from the frontside of the substrate 20. The contact features further include frontside gate contacts (e.g., the VG via 608) electrically coupled to the gate structures from the frontside of the substrate 20. In some embodiments, additional backside S/D contacts are formed to electrically couple to the S/D epitaxy structures in the lower portion of the device 600 (e.g., the S/D epitaxy structures 62L) from the backside of the substrate 20. A silicide layer (e.g., the silicide layer 94) may be formed over the S/D epitaxy structures before forming the S/D contacts.

Furthermore, still referring to FIG. 25, an MLI structure (e.g., the MLI structure 614) electrically coupled to the contact features are then formed at operation 824. The MLI structure includes a plurality of metallization layers configured to provide power supply lines (e.g., the power supply lines Vdd 310 and Vss 320) and signal lines (e.g., the signal lines 350 and 360). In the present embodiments, the power supply lines and the signal lines are respectively coupled (e.g., electrically coupled) to portions of the upper FET 10U and the lower FET 10L in manners consistent with those described with respect to the embodiments of FIGS. 2-19. Additional operations may be subsequently performed at operation 826 to complete fabrication of the device 600.

It will be understood that not all advantages have been necessarily discussed herein, no particular advantage is required for all embodiments or examples, and other embodiments or examples may offer different advantages.

In accordance with one aspect of the present disclosure, a semiconductor device includes a first semiconductor layer and a second semiconductor layer stacked vertically over a substrate. The first semiconductor layer and the second semiconductor layer extend laterally across the substrate. The semiconductor device includes a first gate structure and a second gate structure extending vertically from the substrate and perpendicular to the first semiconductor layer and the second semiconductor layer. The first gate structure engages the first semiconductor layer and the second semiconductor layer to form a first transistor and a second transistor, respectively. The second gate structure engages the first semiconductor layer and the second semiconductor layer to form a third transistor and a fourth transistor, respectively. The first gate structure is laterally adjacent to the second gate structure. The third transistor is an inactive transistor. The second transistor and the fourth transistor are active transistors.

In accordance with another aspect of the present disclosure, a semiconductor device includes a first p-type transistor and a first n-type transistor stacked vertically over a substrate. The semiconductor device includes a second p-type transistor and a second n-type transistor stacked vertically over the substrate. The second p-type transistor is disposed laterally adjacent the first p-type transistor. The second n-type transistor is disposed laterally adjacent the first n-type transistor. The semiconductor device includes a first gate structure and a second gate structure extending from the substrate along a vertical direction. The first p-type transistor and the first n-type transistor each include a portion of the first gate structure. The second p-type transistor and the second n-type transistor each include a portion of the second gate structure. The first p-type transistor and the second p-type transistor are both coupled to a first S/D contact. The first n-type transistor and the second n-type transistor are both coupled to a second S/D contact. The second p-type transistor is a dummy transistor.

In accordance with another aspect of the present disclosure, a semiconductor device includes a top channel layer and a bottom channel layer stacked over a substrate along a first direction and extending lengthwise along a second direction perpendicular to the first direction. The semiconductor device includes a first dielectric structure and a second dielectric structure each extending vertically from the substrate and engaging each of the top channel layer and the bottom channel layer. The semiconductor device includes a first gate structure and a second gate structure spaced apart along the second direction between the first dielectric structure and the second dielectric structure. The first gate structure engages the top channel layer and the bottom channel layer to form a first transistor and a second transistor, respectively. The second gate structure engages the top channel layer and the bottom channel layer to form a third transistor and a fourth transistor, respectively. The third transistor is an inactive transistor. The semiconductor device includes a gate isolation structure separating the second gate structure into a top portion and a bottom portion. The top portion engages the top channel layer, and the bottom portion engages the bottom channel layer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor layer and a second semiconductor layer stacked vertically over a substrate, each of the first semiconductor layer and the second semiconductor layer extending laterally across the substrate; and
a first gate structure and a second gate structure extending vertically from the substrate and perpendicular to the first semiconductor layer and the second semiconductor layer, the first gate structure engaging the first semiconductor layer and the second semiconductor layer to form a first transistor and a second transistor, respectively, and the second gate structure engaging the first semiconductor layer and the second semiconductor layer to form a third transistor and a fourth transistor, respectively, wherein:
the first gate structure is laterally adjacent to the second gate structure,
the third transistor is an inactive transistor, and
the second transistor and the fourth transistor are active transistors.

2. The semiconductor device of claim 1, wherein:
the first transistor and the third transistor are of p-type,
the second transistor and the fourth transistor are of n-type, and
the second semiconductor layer is disposed vertically between the first semiconductor layer and the substrate.

3. The semiconductor device of claim 1, wherein:
the third transistor is coupled to a first source contact, a first drain contact, and a first gate contact,
the fourth transistor is coupled to a second gate contact,
the first source contact and the first drain contact are both coupled to a first signal line, and
the first gate contact and the second gate contact are both coupled to a second signal line.

4. The semiconductor device of claim 1, wherein:
the third transistor is coupled to a first source contact, a first drain contact, and a first gate contact,
the fourth transistor is coupled to a second gate contact,
one of the first source contact and the first drain contact is floating, and
the first gate contact and the second gate contact are both coupled to a same signal line.

5. The semiconductor device of claim 1, wherein:
the third transistor is coupled to a first source contact, a first drain contact, and a first gate contact,
the fourth transistor is coupled to a second gate contact that is further coupled to a first signal line, and
the first gate contact is coupled to power/ground.

6. The semiconductor device of claim 5, wherein the first source contact and the first drain contact are both coupled to a second signal line.

7. The semiconductor device of claim 5, wherein:
one of the first source contact and the first drain contact is coupled to a second signal line, and
the other one of the first source contact and the first drain contact is floating.

8. The semiconductor device of claim 1, further comprising a first dielectric structure and a second dielectric structure each extending vertically from the substrate and engaging with both the first semiconductor layer and the second semiconductor layer, wherein the first gate structure and the second gate structure are disposed in a region between the first dielectric structure and the second dielectric structure.

9. The semiconductor device of claim 5, further comprising a gate isolation structure interposed vertically between the first semiconductor layer and the second semiconductor layer, thereby separating the second gate structure into a first portion coupled to the first gate contact and a second portion coupled to the second gate contact.

10. The semiconductor device of claim 1, wherein:
the second transistor and the fourth transistor share a first common source/drain terminal, and
the first transistor and the third transistor share a second common source/drain terminal.

11. The semiconductor device of claim 1, wherein the third transistor is a first inactive transistor and the first transistor is a second inactive transistor.

12. A semiconductor device, comprising:
a first p-type transistor and a first n-type transistor stacked vertically over a substrate;
a second p-type transistor and a second n-type transistor stacked vertically over the substrate, the second p-type transistor disposed laterally adjacent the first p-type transistor and the second n-type transistor disposed laterally adjacent the first n-type transistor; and
a first gate structure and a second gate structure extending from the substrate along a vertical direction, the first p-type transistor and the first n-type transistor each including a portion of the first gate structure, and the second p-type transistor and the second n-type transistor each including a portion of the second gate structure, wherein:
the first p-type transistor and the second p-type transistor are both coupled to a first source/drain contact,
the first n-type transistor and the second n-type transistor are both coupled to a second source/drain contact, and
the second p-type transistor is a dummy transistor.

13. The semiconductor device of claim 12, wherein:
the first source/drain contact is coupled to a first signal line,
the second p-type transistor is further coupled to a third source/drain contact, and
the third source/drain contact is floating.

14. The semiconductor device of claim 12, wherein:
the first source/drain contact is coupled to a first signal line,
the second p-type transistor is further coupled to a third source/drain contact, and
the third source/drain contact is also coupled to the first signal line.

15. The semiconductor device of claim 12, further comprising a gate isolation structure separating the second gate structure into a first portion included in the second p-type transistor and a second portion included in the second n-type transistor, wherein the first portion is coupled to power/ground.

16. The semiconductor device of claim 15, wherein:
the first source/drain contact is coupled to a first signal line,
the second p-type transistor is further coupled to a third source/drain contact, and
the third source/drain contact is floating, coupled to the first signal line, or coupled to a second signal line different from the first signal line.

17. The semiconductor device of claim 12, further comprising a first dielectric structure and a second dielectric structure each extending from the substrate along the vertical direction, wherein the first gate structure and the second gate structure are parallel to and disposed within a region between the first dielectric structure and the second dielectric structure along a lateral direction.

18. A method of forming a semiconductor device, comprising:
forming a multilayer structure having an upper portion of alternating layers of a first material and a second material, an intermediate layer of a third material, and a lower portion of alternating layers of the first material and the second material;
defining fins in the multilayer structure;
forming a sacrificial gate structure over the fins;
forming trenches in each of the fins;
recessing the first material and the third material exposed in the trenches to form intermediate openings;
depositing a dielectric material in the intermediate openings to form inner spacers and an inner isolation structure between the upper portion and the lower portion;
forming lower source/drain epitaxy structures and upper source/drain epitaxy structures over the inner spacers and the inner isolation structure in the trenches;
replacing the sacrificial gate structure and remaining portions of the first material with lower metal gate structures and upper metal gate structures, wherein each of the lower metal gate structures and the lower source/drain epitaxy structures form a lower transistor and each of the upper metal gate structures and the upper source/drain epitaxy structures form an upper transistor;
forming source/drain contacts and gate contacts coupled to portions of each of the lower transistor and the upper transistor; and
forming metallization layers electrically coupled to at least one of the source/drain contacts and the gate contacts of each of the lower transistor and the upper transistor such that the upper transistor is configured as an inactive transistor and the lower transistor is configured as an active transistor, the metallization layers including power supply lines and signal lines.

19. The method of claim 18, wherein the upper transistor is configured as a p-type transistor and the lower transistor is configured as an n-type transistor.

20. The method of claim 18, wherein forming the metallization layers includes electrically coupling the source/drain contacts of the upper transistor to a same signal line.
